(19) United States
(12) Patent Application Publication
(10) Pub. No.: US 2011/0096595 A1
(43) Pub. Date: Apr. 28, 2011

(54) SEMICONDUCTOR MEMORY DEVICE AND OPERATION METHOD THEREOF

(76) Inventor: Masayuki Terai, Tokyo (JP)

(21) Appl. No.: 12/999,981

(22) PCT Filed: Jun. 19, 2009
(86) PCT No.: PCT/JP2009/061179

§ 371 Date: Dec. 17, 2010

(30) Foreign Application Priority Data
Jun. 20, 2008 (JP) 2008-161674
Nov. 26, 2008 (JP) 2008-301274
Jan. 8, 2009 (JP) 2009-002282

(51) Int. Cl. G11C 11/56; H01L 45/00; H01L 21/02

(52) U.S. Cl. 365/163; 257/4; 438/104; 365/148; 257/E45.003; 257/E21.003

(57) ABSTRACT

Disclosed is a resistance change type nonvolatile memory that has an insulation film structure, is advantageous for the implementation of high integration, and achieves a stable switching characteristic, and a manufacturing method therefor. The memory includes at least an MIM (Metal/Insulator/Metal) structure including an insulation film (2) sandwiched between metal electrodes (1) and (3), and the insulation film (2) includes a laminated structure including a Ta₂O₅ film and a TiO₂ film with a thickness of less than 30 nm. The Ta₂O₅ film is a stoichiometric amorphous film.

### RELATED APPLICATION

This application is the National Phase of PCT/JP2009/061179, filed Jun. 19, 2009, which claims the benefit of Japanese Patent Applications No. 2008-161674, filed on Jun. 20, 2008, No. 2008-301274, filed on Nov. 26, 2008, and No. 2009-002282, filed on Jan. 8, 2009, which are hereby incorporated by reference herein in its entirety.

### TECHNICAL FIELD

This invention relates to a resistance change type device and an operation method of a resistance change type memory using the resistance change type device.

### BACKGROUND

In a non-volatile memory field, a flash memory being the first on the list, ferroelectric memory (Ferbam), MRAM (Magnetic RAM), OUM (Ovonic Unified Memory) and the like have been actively researched.

Recently, a resistance change type non-volatile memory (ReRAM; resistance RAM), which is different from the above mentioned conventional non-volatile memories, has been proposed (Non-Patent Document 1). Non-Patent Document 1 discloses a resistance change type non-volatile memory in which data can be written by setting some degree of resistance in a resistance change layer of a memory cell of the resistance change type non-volatile memory by applying a voltage pulse and the data can be read without destroying the data. Such a non-volatile memory has a possibility of being superior to conventional non-volatile memories because it has a small cell area and is capable of storing a multi value.

A PCMO (Pr_{0.7}Ca_{0.3}MnO₃) and YBCO (YBa₂Cu₃O_{y}) are used for the resistance change layer in Non-Patent Document 1.

Other proposals for a resistance change type non-volatile memory are disclosed in Non-Patent Document 2 and Non-Patent Document 3.

A polycrystalline of NiOₓ (x=1 to 1.5) with a thickness about 50 nm is used as a resistance change layer in Non-Patent Document 2.

It is described that the resistance change layer can be changed into a high or low resistance state by applying a positive voltage on an upper electrode. A fine Crystalline TiO₂ layer of 80 nm thickness is used as a resistance change layer in Non-Patent document 3. Two operation methods are described in Non-Patent document 3. One operation method is that the resistance becomes low by applying a negative (positive) voltage on an upper electrode and becomes high by applying a positive (negative) voltage (bipolar operation). The other, is that the resistance becomes low or high by applying only a positive (negative) voltage (unipolar operation). The switching mechanism of the ReRAM using TiO₂ as the resistance change layer is estimated as follows. A filament is formed in the TiO₂ by the first application of a high voltage (designated as “Forming”) and the switching operation is induced by a change of resistance of the filament (Non-Patent Document 4). The switching (Reset) from a low resistance state to a high resistance state occurs by applying either a positive voltage or a negative voltage on the upper electrode. When applying a positive voltage on the upper electrode, a resistance of a portion of the filament in the vicinity of the upper electrode becomes large and when applying a negative voltage on the upper electrode, a resistance of a portion of the filament in the vicinity of the lower electrode becomes large (Non-Patent Document 5). It is thus conceived that an anode oxidation of the filament is one of candidates of the switching mechanism of the ReRAM.

### [Non-Patent Document 1] W. W. Zhuang et. al., 2002 IEDM, 7.5, December 2002.

### [Non-Patent Document 2] G.-S. Park et. al., APL, Vol. 91, pp. 222103, 2007.

### [Non-Patent Document 3] C. Yoshida et. al., APL, Vol. 91, pp. 223510, 2007.

### [Non-Patent Document 4] K. Kinoshita et. al., JJAP, Vol. 45, no. 37, L991-L994, 2006.

### [Non-Patent Document 5] K. Kinoshita et. al., APL, Vol. 89, pp. 103509, 2006.

### SUMMARY

It should be noted that the content disclosed in Non-Patent Documents 1 to 5 is hereby incorporated by reference herein in its entirety. The following analysis is given by the present invention.

With the advancement of miniaturizing a resistance change type non-volatile memory, using polycrystalline or fine crystalline materials for the resistance change layer as described in Non-Patent Documents 1 to 3, a crystal grain size cannot be negligible any more as compared with a device size. Specifically, there is a problem that an amount of a device-to-device variation in an electric characteristic becomes large due to roughness of a surface of the resistance change layer depending on crystal grains.

The roughness of the surface of the resistance change layer can be reduced by making the resistance change layer as a thin film. However, if the resistance change layer is made thin, the switching operation cannot be obtained due to an increase of a leakage current, and therefore, a thickness of the resistance change layer has been set as 50 nm or more. If a ReRAM of a symmetrical structure in which a single resistance change layer is sandwiched between an upper electrode and a lower electrode is used, there is a problem as follows.

FIG. 32A shows a ReRAM of a symmetrical structure, in which a single layer made of a transition metal oxide (TMO) as a resistance change layer is sandwiched between upper and lower electrodes (designated as upper electrode (top electrode) T.E. and as lower electrode (bottom electrode) B.E., respectively). FIGS. 32B and 32C are diagrams for explaining problems when using the ReRAM shown in FIG. 32A.

FIG. 32B shows a relation of an upper electrode current (I_{T.E.}) and a voltage applied on the upper electrode (V_{T.E.}) in switching and read operation when the ReRAM has a unipolar operation mode, while FIG. 32B shows the relation when the ReRAM has a bipolar operation mode.

In case of the unipolar operation mode, as shown in FIG. 32B, a Reset operation (switching from a low resistance state to a high resistance state) is performed at a voltage lower than that for a Set operation (switching from a high resistance state to a low resistance state). However, since a difference of the voltage of the Reset operation from a Read voltage (V_{T.E.} for Read) is small, the resistance becomes high by a Read-disturbance and hence a possibility of an occurrence of a malfunction is high.

In case of the bipolar operation mode, as shown by a solid line in FIG. 32C, it seems that the possibility of the resistance becoming high by a read-disturbance is small at a glance. However, when using the ReRAM of a symmetrical structure shown in FIG. 32A, there is also a high possibility of failure by the read-disturbance because the resistance of both parts of the filament in the vicinity of the upper electrode and the lower electrode can become high and thus there is a potential high resistance failure as shown by a broken line.

Main evaluation items for reliability of a non-volatile memory (NVM) are as follows.
retention characteristic;
tolerance against a program-disturbance; and
tolerance against a read-disturbance.

In case of a ReRAM having one transistor and one resistance (1T1R), there is no program disturbance. Because the ReRAM is a two-terminal device, the tolerance against a read-disturbance becomes more important than the retention characteristic.

It has been difficult to enhance an yield of the conventional ReRAM product because the resistance change layer is deteriorated much by sputtering used in forming an upper electrode thereof.

Accordingly, it is an object of the present invention to provide a resistance change type non-volatile memory including an insulation film structure advantageous for high integration and can realize a stable switching characteristic, and an operation method thereof. It is another object of the present invention to provide a reliable resistance change type non-volatile memory having a high tolerance against a read-disturbance.

In accordance with an aspect of the present invention, there is provided a resistance change type memory device comprising at least an MIM (Metal/insulator/Metal) structure in which an insulation film is sandwiched between metal electrodes, wherein the insulation film includes a laminated structure including a Ta₂O₅ film and a TiO₂ film which has a thickness of less than 30 nm. The Ta₂O₅ film is a stoichiometric amorphous film.

According to the present invention, there is provided an operation method of a resistance change type memory device, comprising:

applying a voltage across an upper electrode and a lower electrode to make a resistance between the upper electrode and the lower electrode lower than a resistance of a single layer of the Ta₂O₅.

According to the present invention, a resistance change type memory device being advantageous for high integration and having a stable switching characteristic can be realized. Also, a reliable memory device having a high tolerance against a read-disturbance can be realized.

According to the present invention, a fabrication yield of the device can be improved.

Still other features and advantages of the present invention will become readily apparent to those skilled in this art from the following detailed description in conjunction with the accompanying drawings wherein only exemplary embodiments of the invention are shown and described, simply by way of illustration of the best mode contemplated of carrying out this invention. As will be realized, the invention is capable of other and different embodiments, and its several details are capable of modifications in various obvious respects, all without departing from the invention. Accordingly, the drawing and description are to be regarded as illustrative in nature, and not as restrictive.

### BRIEF DESCRIPTION OF THE DRAWINGS

FIG. 1 is a diagram schematically illustrating a sectional structure of a resistance change type memory device according to an exemplary embodiment of the present invention.

FIGS. 2A and 2B are diagrams showing XPS spectrum measurement results of a TiO₂ layer of a resistance change type memory device according to an example of the present invention.

FIGS. 3A and 3B are diagrams showing RMS measurement results of a Ta₂O₅ layer of a resistance change type memory device according to an example of the present invention.

FIG. 4 is a diagram showing an XRD spectrum measurement result of a Ta₂O₅ layer of a resistance change type memory device according to an example of the present invention.

FIGS. 5A to 5C are diagrams illustrating switching characteristics of Ta₂O₅/TiO₂ laminated structures (Samples 3 to 5) according to one example of the present invention.

FIG. 6 is a diagram showing initial leakage currents of a Ta₂O₅ single layer structure (Sample 2) and a Ta₂O₅/TiO₂ laminated structure (Sample 4), and a current characteristic after Forming of the Ta₂O₅/TiO₂ laminated structure (Sample 4).

FIG. 7 is a diagram illustrating a configuration of an example (resistance change type memory of one transistor and one resistance) of the present invention.

FIGS. 8A to 8G are sectional process diagrams illustrating the procedure of a fabrication method of an example (resistance change type memory of one transistor and one resistance) of the present invention.

FIG. 9 shows a SIMS profile of a Ta₂O₅/TiO₂ laminated structure,

FIG. 10 shows a diagram for illustrating a configuration of Example 2 of the present invention.

FIG. 11 shows a TEM image of a Pt/Ta₂O₅ (10 nm)/TiO₂ (3 nm).

FIG. 12 shows a nano-beam electron diffraction image of a TiO₂ layer,

FIG. 13 shows an EELS spectrum of a TiO₂ layer.

FIGS. 14A to 14H are sectional process diagrams illustrating the procedure of a fabrication method of Example 2 of the present invention.

FIG. 15 is a diagram for explaining an operation of the present example of the present invention.

FIG. 16 is a diagram showing examples of a DC switching characteristics at Set time and Reset time.

FIG. 17 is a diagram showing an example of a relation between a saturated current of a transistor and a resistance after set and a reset current.

FIG. 18 is a diagram showing an example of a read current characteristic in a resistance state.

FIGS. 19A and 19B are diagrams showing examples of dependence of resistances after Set (low resistance state: R_{L}) and after Reset (high resistance state: R_{H}) on the number of rewriting.

FIGS. 20A and 20B are diagrams showing examples of retention characteristic of R_{H} and R_{L} under high temperature stress at 85° C. FIGS. 21A and 21B are diagrams showing examples of read-disturbance tolerance of R_{H} and R_{L} under a normal temperature.

FIGS. 22A and 22B are diagrams showing examples of read-disturbance tolerance (variation rate of R_{L} and R_{H}) under high voltage stress at 85° C.

FIG. 23 is a diagram illustrating a sectional structure of Example 3 of the present invention.

FIG. 24 illustrates roughness of lower electrodes of Example 3 of the present invention and that of a comparative example (lower electrode: single layer of Ru).

FIGS. 25A and 25B are diagrams showing inter-chip variations of a current characteristic at Forming in Example 3 and a comparative example.

FIG. 26 is a diagram showing, for comparison, Forming voltage distribution, Set voltage distribution and Reset voltage distribution of Example 3 of the present invention and a comparative example.

FIG. 27 is a diagram showing, for comparison, resistance distribution after Set and resistance distribution after Reset of the present example of the present invention and a comparative example.

FIGS. 28A and 28B are diagrams showing, for comparison, a change of Reset resistance distribution under high-temperature stress at 190° C. of Example 3 of the present invention a comparative example.

FIGS. 29A to 29H are sectional process diagrams illustrating the procedure of a fabrication method of Example 3 of the present invention.

FIG. 30 is a diagram illustrating a sectional structure of Example 4 of the present invention.

FIGS. 31A to 31E are sectional process diagrams illustrating the procedure of a fabrication method of Example 4 of the present invention.

FIG. 32A illustrates a ReRAM of a symmetric arrangement, and FIGS. 32B and 32C are diagrams explaining characteristics of I_{T.E.}-V_{T.E.} at Switching time and Read time under a unipolar operation mode and a bipolar operation mode, respectively.

FIG. 33 is a diagram illustrating a sectional structure of Example 5 of the present invention.

FIG. 34 is an XRD spectrum of Ta₂O₅ film and TaSiO film after annealing at 750° C. for 30 minutes.

FIG. 35 is a diagram illustrating DC switching characteristics of Example 5 of the present invention at Forming time, Set time and Reset time.

FIGS. 36A to 36H are sectional process diagrams illustrating the procedure of a fabrication method of Example 5 of the present invention.

### PREFERRED MODES

Principles of the operation of the present invention will now be described. A resistance change type memory device according to the present invention comprises an MIM (Metal/Insulator/Metal) structure in which an insulation film is sandwiched between an upper electrode (top electrode or second electrode) and a lower electrode (bottom electrode or first electrode). The insulation film includes a laminated structure including a Ta₂O₅ film and a TiO₂ film which has a thickness of less than 30 nm. TiO₂, which is of a fine crystalline structure, is a thin film with a thickness of less than 30 nm and Ta₂O₅ is in an amorphous state and flat. As a result, a roughness of a surface of the Ta₂O₅/TiO₂ laminated film can be reduced.

According to the present invention, even if a resistance change type device is miniaturized, a device-to-device variation of an electric characteristic caused by roughness of a surface of the resistance change layer can be improved.

In a resistance change type memory device according to the present invention, a low-resistance switching path is to be formed in advance in a Ta₂O₅ layer, when a specified voltage is applied across upper and lower electrodes.

The Ta₂O₅ layer is homogenously amorphous, as described above, a switching path with a small device-to-device variation can be formed.

In a resistance change type memory device according to the present invention, a low resistance state can be switched into a high resistance state by applying a specified positive voltage on an electrode that is in contact with the TiO₂ layer or a negative voltage on an electrode that is in contact with the Ta₂O₅ layer.

According to the present invention, as described above, a resistance change type memory device that is advantageous for high integration, has a small variation and has stable electric characteristics can be realized.

In addition, because the resistance change layer is asymmetric and has a laminated film including a Ta₂O₅ layer that is not switched, a potential Reset failure during a bipolar operation can be reduced and the read-disturbance tolerance an be improved. The present invention will be described with exemplary embodiments.

### Exemplary Embodiments

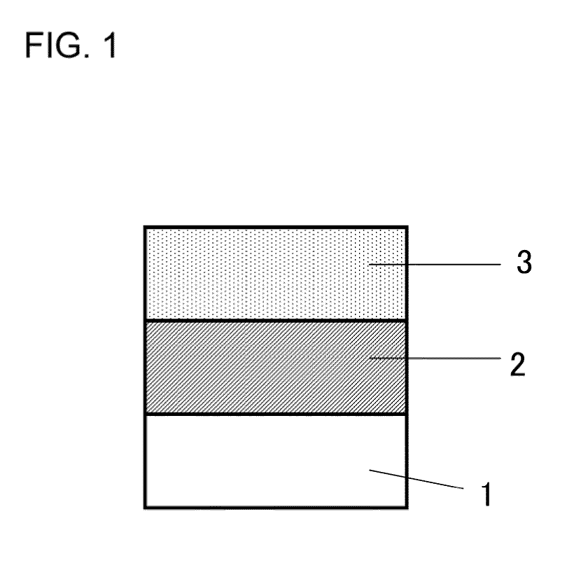

FIG. 1 is a diagram showing schematically a sectional view of a resistance change type memory device according to an exemplary embodiment of the present invention. The semiconductor device of this exemplary embodiment includes a resistance change type memory device including at least an MIM (Metal/Insulator/Metal) structure in which an insulation layer (insulation film) 2 is sandwiched between a lower electrode 1 and an upper electrode 3. The insulation layer 2 includes a laminated structure comprising a Ta₂O₅ film and a TiO₂ film with a thickness of less than 30 nm. The Ta₂O₅ layer is preferably stoichiometric amorphous. The TiO₂ layer may be formed between the upper electrode and the Ta₂O₅ layer; however, the TiO₂ layer is preferably formed between the lower electrode and the Ta₂O₅ layer. The TiO₂ layer is formed between the lower electrode 1 and the Ta₂O₅ layer.

Each of the Ta₂O₅ layer and TiO₂ layer with a thickness of less than 30 nm does not function as a resistance change type memory device by alone.

The inventor of the present invention has found by experiments that a Ta₂O₅ film and a TiO₂ film with a thickness of less than 30 nm function as a resistance change type memory device only when they are laminated.

The lower electrode 1 suffices to be electrically conductive. The lower electrode 1 may be formed of, for example, Au, Ni, Co, Pt, Ru, Ir, Ti, Cu, Ta, Iridium-tantalum alloy (Ir—Ta), Indium Tin Oxide (ITO), or an alloy thereof, or an oxide, nitride, fluoride, carbide or silicide thereof. A laminated structure of these materials may also be used.

The upper electrode 3 suffices to be electrically conductive. The upper electrode 3 may be formed of, for example, Au, Ni, Co, Pt, Ru, Ir, Ti, Cu, Ta, Iridium-tantalum alloy (Ir—Ta), Indium Tin Oxide (ITO), or an alloy thereof, or an oxide, nitride, fluoride, carbide or silicide thereof. A laminated structure of these materials may also be used.

In the MIM structure included in the resistance change type device, it suffices that at least a part of the adjacent layers are laminated each other.

The resistance change type memory device includes an operation for making a resistance between the upper electrode and the lower electrode lower than a resistance of the Ta₂O₅ single layer itself by applying a voltage across the upper and lower electrodes.

By applying a positive voltage on an electrode that is in contact with the TiO₂ layer, after operation of making the resistance between the upper and lower electrodes lower than the resistance of the Ta₂O₅ single layer (Forming), a high resistance state is switched into a low resistance state or a low resistance state is switched into a high resistance state and the resistance can be retained.

Followings are experimental results which show that a function of a resistance change type device can become effective by laminating a Ta₂O₅ film and a TiO₂ film with a thickness of less than 30 nm.

TABLE 1

| | TiO₂ film | Ta₂O₅ film |
|---|---|---|
| Sample 1 | 17 nm | x |
| Sample 2 | x | 13 nm |
| Sample 3 | 17 nm | 10 nm |
| Sample 4 | 17 nm | 13 nm |
| Sample 5 | 17 nm | 15 nm |
| Sample 6 | 30 nm | 13 nm |

The materials shown in Table I are prepared for experiments.

In Sample 1 (comparative example 1), a TiO₂ single film with a thickness of 17 nm is used as an insulation layer of the MIM.

In Sample 2 (comparative example 2), a Ta₂O₅ single film with a thickness of 13 nm is used as an insulation layer of the MIM.

In Sample 3 (exemplary embodiment), a TiO₂ film with a thickness of 17 nm and a Ta₂O₅ film with a thickness of 10 nm is used as an insulation layer of the MIM.

In Sample 4 (exemplary embodiment), a TiO₂ film with a thickness of 17 nm and a Ta₂O₅ film with a thickness of 13 nm are used as an insulation layer of the MIM.

In Sample 5 (example), a TiO₂ film with a thickness of 17 nm and a Ta₂O₅ film with a thickness of 15 nm are used as an insulation layer of the MIM.

In Sample 6 (exemplary embodiment), a TiO₂ film with a thickness of 30 nm and a Ta₂O₅ film with a thickness of 15 nm are used as an insulation layer of the MIM.

At first, a Ti film with a thickness of 5 nm and a Ru film with a thickness of 40 nm are formed successively on a semiconductor substrate at a normal temperature using a DC sputtering equipment to form a lower electrode.

Then a titanium oxide film with a thickness of 17 or 30 nm is formed by performing reactive sputtering in a DC sputtering equipment.

A titanium oxide film is not formed in Sample 2.

Ti is used as a sputtering target and O₂ and Ar are flown with a flow ratio of 0, and Ar being set to 1:5. The pressure in a chamber is set to 10 m Torr, a deposition temperature is set to 300° C. and the power is set to 4.2 kW.

The composition of the deposited Ti oxide film is evaluated using an XPS (X-ray photoemission spectroscopy).

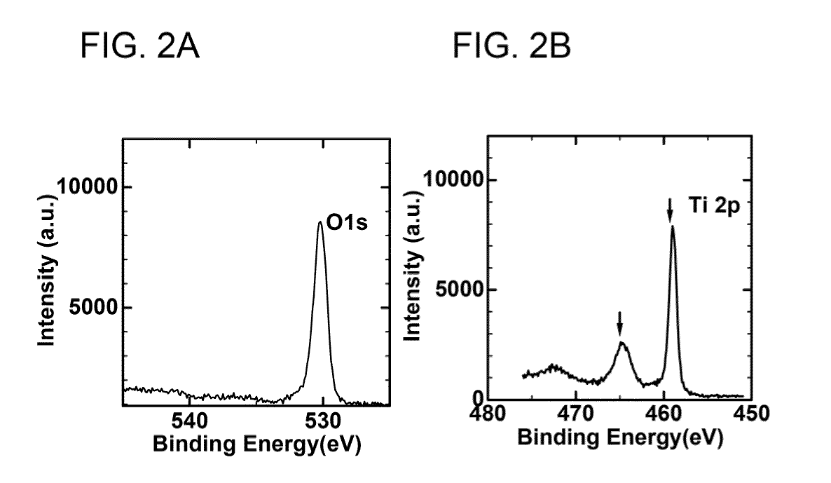

FIGS. 2A and 2B show XPS spectrums of an O(1s) (525 to 545 eV) orbital and a Ti(2p) (450 to 480 eV) orbital, respectively. An Al(kα) ray is used as an X-ray source.

A composition ratio (O/Ti) of the titanium oxide film obtained from peak areas of the O(1s) and Ti(2p) is almost 2 and it has been found that TiO₂ is formed.

Next, a Ta oxide film is formed using an RF sputtering equipment. A Ta₂O₅ is used as a sputtering target and 10 sccm of O₂ gas and 5 sccm of Ar gas are flown. The deposition temperature is set to 350° C. and the power is set to 2 kW.

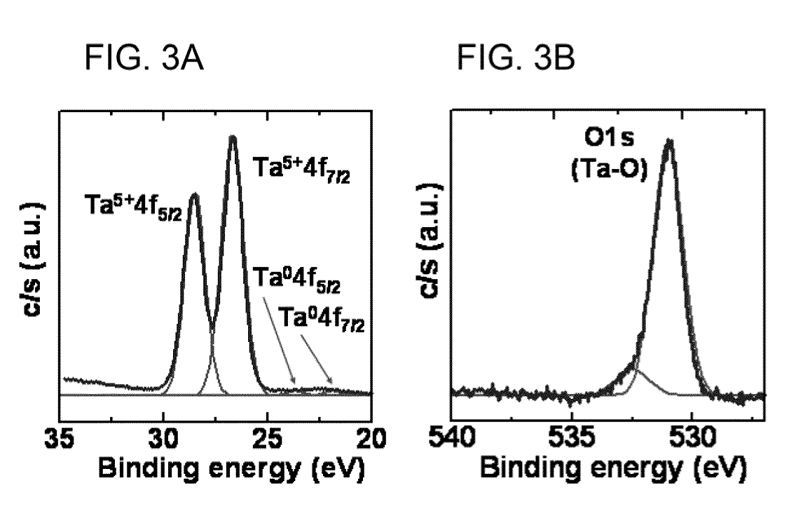

A composition of the tantalum oxide film is evaluated using an XPS (X-ray photoemission spectroscopy). FIGS. 3A and 3B show XPS spectrums of a Ta(4f) (15 to 35 eV) orbital and an O(1s) (525 to 545 eV) orbital. An Al(kα) ray is used as an X-ray source.

As shown in FIG. 3A, in a region of Ta(4f), two peaks of Ta⁵⁺(4f_{5/2}) and Ta⁵⁺(4f_{7/2}) from Ta₂O₅, and two peaks of Ta⁰(4f_{5/2}) and Ta⁰(4f_{7/2}) with a weak intensity from metal Ta are observed. On the other hand, as shown in FIG. 3B, in an O(1s) region, peaks from Ta—O bonding are observed.

A composition ratio (O/Ta) of the tantalum oxide film obtained from peak areas is 2.5 and it has proved that a stoichiometric Ta₂O₅ film is formed.

Next, an XRD (X-Ray diffraction) evaluation is performed to search a crystalline characteristic and crystallization temperature of the Ta₂O₅ film. A Ta₂O₅ film is deposited on a Si substrate and hen annealed at a temperature of 500° C. to 700° C. in an oxygen atmosphere.

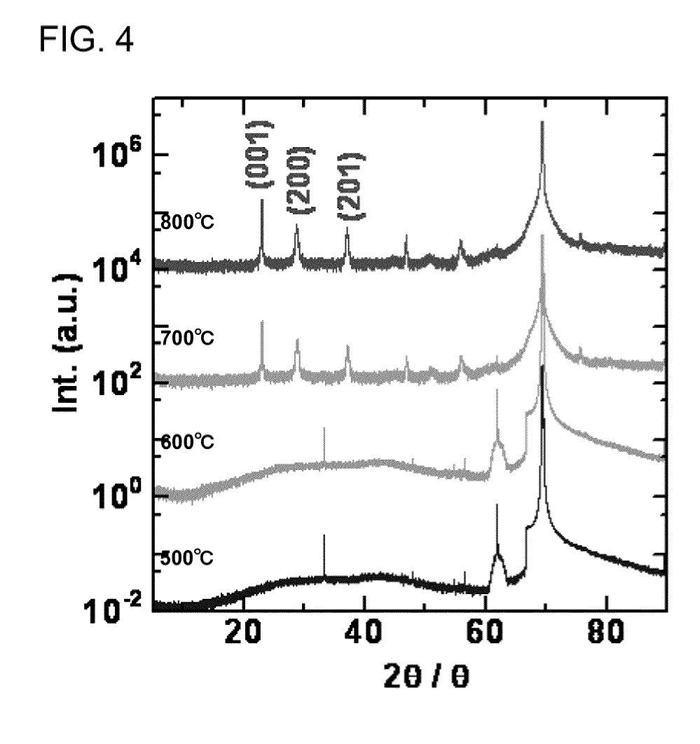

FIG. 4 shows an XRD spectrum. As shown in FIG. 4, it is confirmed that the Ta₂O₅ film is crystallized at a temperature of 700° C. or more and crystal faces (001), (200) and (201) are formed. (Peaks observed at a temperature less than 700° C. are from Si substrate.)

The Ta₂O₅ film is amorphous because a high temperature annealing at a temperature of 700° C. or more is not performed in the present experiment.

When a non-volatile memory device (resistance change type memory device) of the present invention is mounted on an interconnect layer in an integrated circuit, a Ta₂O₅ film will remain amorphous because a process temperature of the interconnect layer is 600° C. or less.

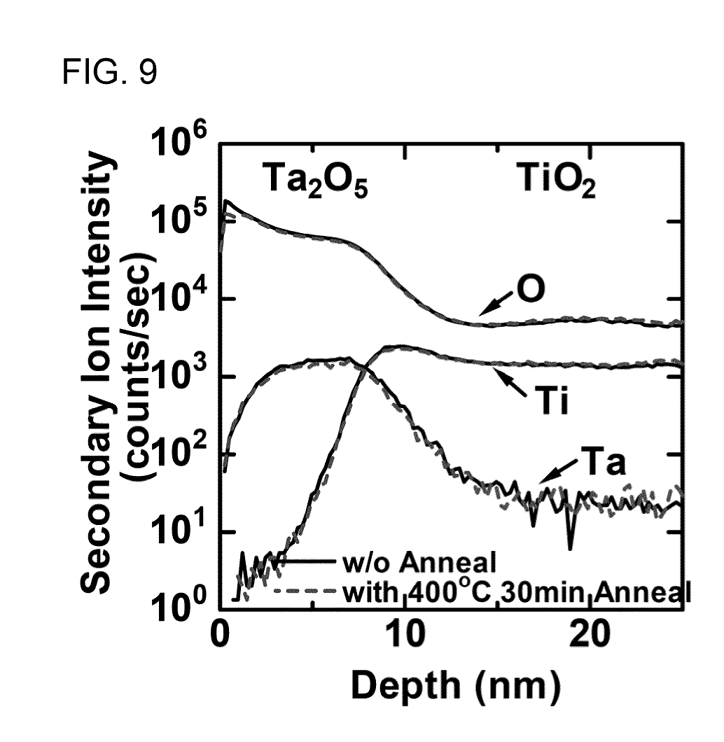

FIG. 9 shows a SIMS profile of the Ta₂O₅/TiO₂ laminated film. A solid line (w/o Anneal) indicates a result of a material without additional annealing after forming the laminated film and dotted line (with 400° C., 30 min, Anneal) indicates a result of a material that an additional annealing is performed at 400° C. for 30 minutes.

As shown in FIG. 9, the Ta₂O₅/TiO₂ laminated film of the experiment includes a mutual diffusion (counter diffusion) layer around the interface in which Ti in the TiO₂ film diffuses into the Ta₂O₅ film. However, Ti does not diffuse up to the surface of the Ta₂O₅ film and therefore, the Ta₂O₅ film is stoichiometric around the surface area.

After deposition of the laminated film, it is additionally annealed at 400° C. for 30 minutes; however, no change is observed. The result shows that the laminated film is stable and has a high temperature resistance.

After formation of the Ta₂O₅ film, a Pt film as an upper electrode is formed using an electron-gun vapor deposition method. A pattern of the upper electrode is formed using a stencil mask.

The samples prepared in such a way are evaluated on the points of a initial leakage current between the upper and lower electrodes and a switching characteristic. The shape of the electrode is a square having 25 μm length of each side.

The switching characteristic is evaluated after making a resistance of the insulation layer low by applying positive biased voltage on the lower electrode (referred to “Forming” hereinafter). A current path (switching path) is formed in the insulation layer of the MIM by the Forming step and the switching phenomena occurs in the current path. The results are shown in Table 2.

TABLE 2

| | | Switching |
|---|---|---|
| | Initial leakage current | characteristics |
| Sample 1 | x | x |
| Sample 2 | | x |
| Sample 3 | ∘ | ∘ |
| Sample 4 | ∘ | ∘ |
| Sample 5 | ∘ | ∘ |
| Sample 6 | ∘ | x |

In the Table 2, a sample having a large initial leakage current of 1E-5A or more under an applied voltage of 1 V is indicated by “x” and a sample having a small initial leakage current of less than 1E-5A, which means good insulation, under an applied voltage of 1 V is indicated by “∘”. Also in the Table 2, a sample that did not have a switching characteristic is indicated by “x” and a sample that showed a switching characteristic is indicated by “∘”.

As shown in Table 2, Sample 1, in which a TiO₂ single film is used as an insulation layer, showed a very large initial leakage current and had no switching characteristic. That is because the thickness of the TiO₂ film is as thin as 17 nm.

Sample 2, which used a Ta₂O₅ single film, had a low initial leakage current but showed no switching characteristic. There has been no report in papers or the like regarding switching characteristic of a Ta₂O₅ film.

On the other hand, Samples 3 to 5, in which a TiO₂ film with a thickness of 17 nm and a Ta₂O₅ film are laminated, had a low initial leakage current and showed a switching characteristic after Forming by applying a positively biased voltage on the lower electrode.

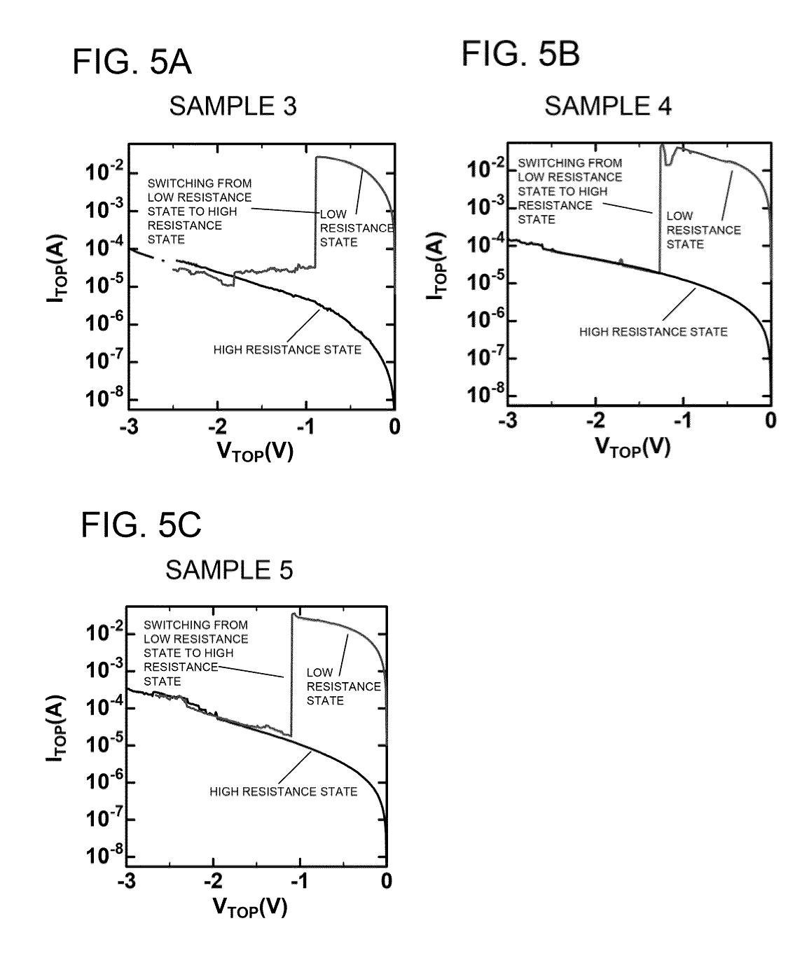

FIGS. 5A to 5C show switching characteristics of resistance change type devices of Samples 3 to 5.

Samples 3 to 5 are changed (switched) from a low resistance state into a high resistance state by applying a positively biased voltage on the lower electrode contacted with the TiO₂ film, that is, applying a negatively biased voltage on the upper electrode in this case, but not changed from a low resistance state into a high resistance state by applying an inversely biased voltage. It is supposed that the reason for this is that the switching into a high resistance state is based on a diffusion of oxygen ion (O⁻) in a direction to an electrode which is in contact with the TiO₂ layer and an oxidation of an anode.

That is, it is supposed that the oxygen ion (O⁻) diffuses in a direction to an electrode which is in contact with the TiO₂ layer by an electric field in the TiO₂/Ta₂O₅ laminated film and an oxidation reaction of a switching path occurs in the TiO₂ layer or at an interface between the TiO₂ layer and the Ta₂O₅ layer.

It has been found by an experiment that the switching path in the TiO₂/Ta₂O₅ laminated film is formed from the TiO₂ layer to penetrate into the Ta₂O₅ layer.

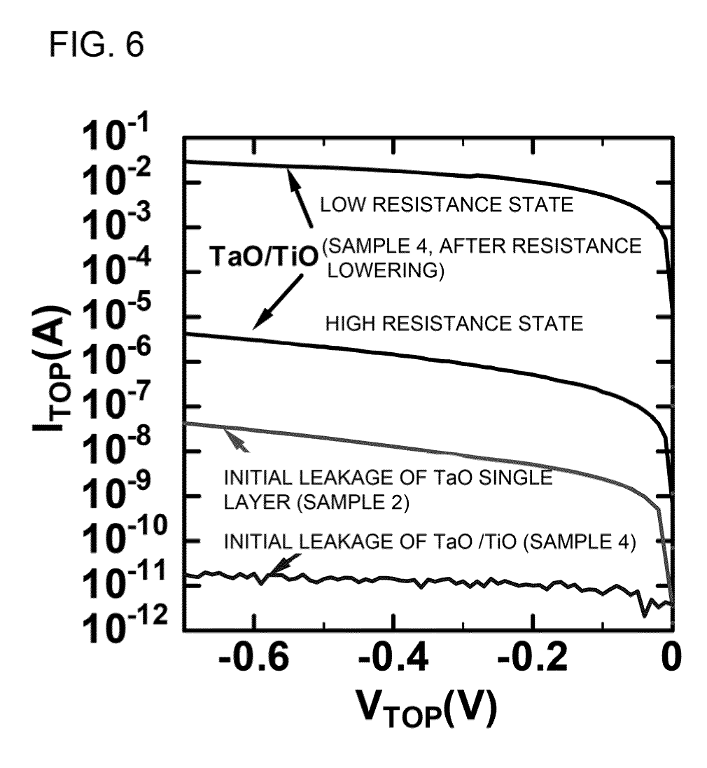

FIG. 6 shows initial leakage currents of a Ta₂O₅ single layer structure (Sample 2) and a Ta₂O₅/TiO₂ laminated structure (Sample 4), and current characteristics at a low resistance state and a high resistance state after Forming of the Ta₂O₅/TiO₂ laminated structure (Sample 4).

As shown in FIG. 6, the current between the upper and lower electrodes of the Ta₂O₅/TiO₂ laminated structure (Sample 4) in a high resistance state after Forming is larger than the initial leakage current of the Ta₂O₅ single layer structure (Sample 2). It can be said that a resistance of the Ta₂O₅ layer of the Ta₂O₅/TiO₂ laminated structure (Sample 4) becomes smaller than a resistance before Forming.

That is, it has been found that a switching path is formed also in the Ta₂O₅ layer of the Ta₂O₅/TiO₂ laminated structure (sample 4) by the Forming process.

As described above, the resistance change phenomenon occurs along the switching path in the TiO₂ layer or at the interface between the TiO₂ layer and the Ta₂O₅ layer. Thus, by setting the TiO₂ layer downside and the Ta₂O₅ layer upside, suffering from a damage caused by the sputtering during the deposition of an upper electrode can be relatively made small and a stable switching operation can be obtained.

In a case where the thickness of the TiO₂ layer is increased up to 30 nm, although the sample is a laminated film of the TiO₂ layer and the Ta₂O₅ layer, it did not show switching operation as shown by Sample 6 in Table 2. One of the reasons of the result is an increase of roughness in the surface of the TiO₂ layer due to an increase of the thickness of the TiO₂ layer.

It has been found that, by the experimental results above described, the function of a resistance change type device can become effective by using a laminated film including a Ta₂O₅ film and a TiO₂ film with a thickness of less than 30 nm for an insulation layer of the MIM structure.

According to a resistance change layer of a resistance change type non-volatile memory of the present invention, the roughness of the surface of the Ta₂O₅/TiO₂ laminated film can be reduced by making the thickness of the fine crystalline TiO₂ film less than 30 nm and making the Ta₂O₅ film amorphous and flat.

As a result, according to the present invention, even when a resistance change type device is miniaturized, a device-to-device variation in an electrical characteristic caused by roughness of a surface of a resistance change layer can be improved.

In addition, according to the present invention, a fabrication yield of the device can be improved because the Ta₂O₅ layer has a role to lighten sputtering damage during the deposition of the upper electrode.

In a resistance change type memory device of the present invention, a specified voltage (Forming voltage) has to be applied across the upper and lower electrodes, and a switching path has to be formed so as to penetrate though the TiO₂ layer and the Ta₂O₅ layer. However, because the Ta₂O₅ layer is homogenously amorphous, switching path having a small device-to-device variation can be formed.

Besides that, by making the resistance change layer asymmetric and laminated with the Ta₂O₅ layer that has no switching characteristic, a potential Reset failure in the bipolar operation can be reduced and the tolerance against a read-disturbance can be improved.

### Example 1

Next, an example in which a semiconductor of the present invention is applied to a ReRAM of 1T1R (one-transistor and one-resistor) type will be described.

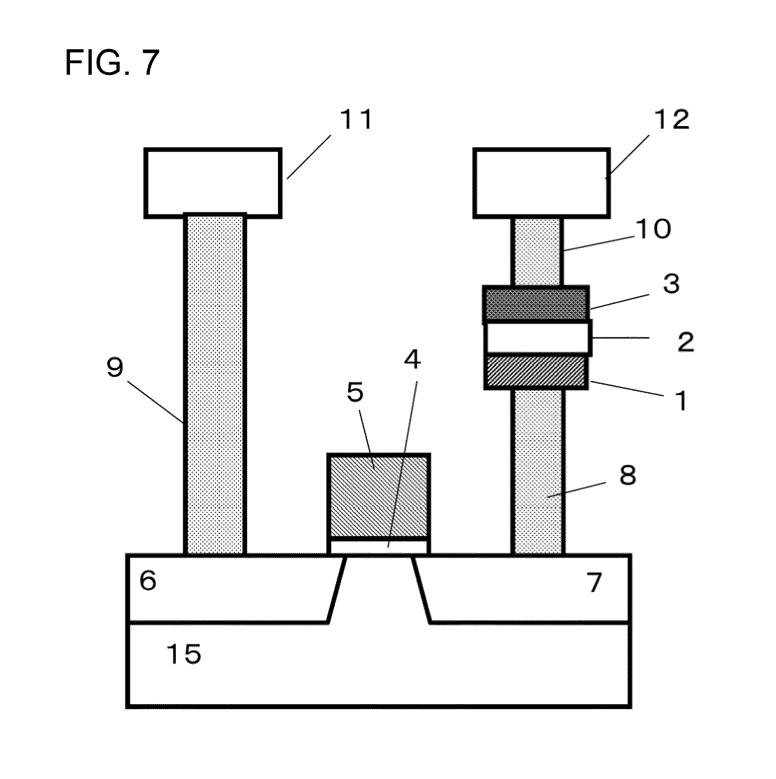

FIG. 7 schematically illustrates a sectional view of a 1T1R-type ReRAM in which an MIM device of a resistance change type non-volatile memory of the present invention is provided.

Referring to FIG. 7, a control transistor is formed in which a gate insulation film 4, a gate electrode 5 and source/drain 6 and 7 are formed on a semiconductor substrate 15. A via 8 is formed so as to connect to the source/drain 7. An MINI structure, in which a lower electrode 1 which is arranged so as to connect to the via 8, an insulation layer 2 which is a laminated structure including a Ta₂O₅ film and a TiO₂ film with a thickness of less than 30 nm and an upper electrode 3 are laminated in this order, is formed. A via 10 is formed on the upper electrode 3, and a second interconnect layer 12 (wiring formed by patterning on an interconnect layer) is formed so as to connect to the via 10. A via 9 is formed so as to connect to the source/drain 6, and a first wiring 11 (wiring formed by patterning on an interconnect layer) is formed so as to connect with the via 9.

An N-type field-effect transistor (NFET) or a P-type field-effect transistor (PFET) may be used as a control transistor. An NFET is used in Example 1.

A gate oxide film is used as the gate insulation film 4. A hafnium oxide film, a zirconium oxide film, an alumina or a silicate or a nitride thereof, or a laminated film thereof may be used.

As for the gate electrode 5, a phosphorous-doped polysilicone is used in Example 1. A metal gate or a silicide gate may be used.

The lower electrode 1 basically suffices to be electrically conductive. The lower electrode 1 may be formed of, for example, Au, Ni, Co, Pt, Ru, Ir, Ti, Cu, Ta, Iridium-tantalum alloy (Ir—Ta), Indium Tin Oxide (ITO), or an alloy thereof, or an oxide, nitride, fluoride, carbide or silicide thereof. A laminated structure of these materials may be also used. An electrode made of Ru is used in Example 1.

The upper electrode 3 basically suffices to be electrically conductive. The upper electrode 3 may be formed of, for example, Au, Ni, Co, Pt, Ru, Ir, Ti, Cu, Ta, Iridium-tantalum alloy (Ir—Ta), Indium Tin Oxide (ITO), or an alloy thereof, or an oxide, nitride, fluoride, carbide or silicide thereof. A laminated structure of these materials may be also used. An electrode made of Ru is used in Example I.

An order of the TiO₂ film and the Ta₂O₅ film in the insulation layer (or called as “resistance change layer”) 2 does not matter. However, arranging the TiO₂ layer at lower side is preferable from a viewpoint of reducing influence of sputtering damage during a deposition of the upper electrode because a place at which a resistance changes is in the TiO₂ film or at the interface between the TiO₂ film and the Ta₂O₅ film. In the present example, a TiO₂ film with a thickness of 17 nm is deposited first and then a Ta₂O₅ film with a thickness of 13 nm is formed consecutively.

Next, an operation of the semiconductor of the present example will be described.

In order to perform Forming, a resistance of the insulation layer (resistance change layer) 2 is made lower by applying a positive voltage on the first interconnect layer 11 and the gate electrode 5. At this time, a resistance of the insulation layer (resistance change layer) 2 is set to a desired value by controlling the voltage applied on the gate electrode 5 and limiting a current by the control transistor. The Forming can be performed by applying a positive voltage on the second interconnect layer 12 instead of on the first interconnect layer 11.

When switching from a low resistance state to a high resistance state, a positive voltage is applied on the first interconnect layer 11 and the gate electrode 5.

For switching from a high resistance state to a low resistance state, a positive voltage is applied on the first interconnect layer 11 and the gate electrode 5. At this time, a voltage higher than that for switching to a high resistance state is applied on the first interconnect layer 11. The resistance change layer 2 is set to a desired resistance value by controlling a voltage applied on the gate electrode 5 and limiting a current by the control transistor.

For switching from a high resistance state to a low resistance state, a positive voltage may be applied on the second interconnect layer 12 instead of on the first interconnect layer 11.

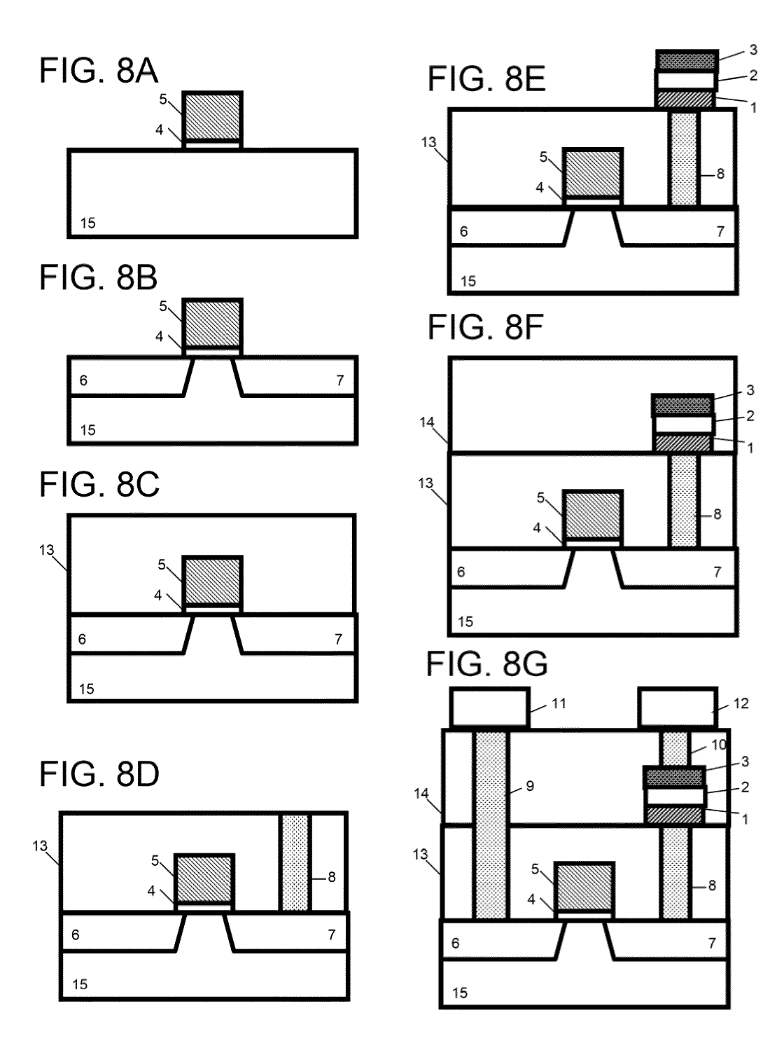

FIGS. 8A to 8G are diagrams illustrating the procedure of a fabrication method of a 1T1R-type ReRAM of the present example. The fabrication method of the present example will be described with reference to FIGS. 8A to 8G.

At first, as shown by FIG. 8A, a gate oxide film 4 and a phosphorous-doped polysilicone 5 are deposited on a semiconductor substrate 15 and then a gate electrode 5 is formed by patterning of the layers by an exposure process and a dry-etching process.

Next, as shown by FIG. 8B, source/drain regions 6 and 7 are formed by doping phosphor with a dose of 2E+15 cm⁻², using the gate electrode 5 as a mask.

Next, as shown by FIG. 8C, a first interlayer insulation film 13 is deposited on the entire surface of the semiconductor substrate 15 and a surface of the first interlayer insulation film 13 is flattened by a CMP (Chemical Mechanical Polishing) method. An oxide film is used for the first interlayer insulation film 13 in the present example.

Next, the first interlayer insulation film 13 is exposed and dry-etched to form a via and TiN (titanium nitride) and W (tungsten) are deposited.

As shown by FIG. 8D, the surface is flattened by CMP and the TiN and W other than the via portion are removed to form the via 8.

Next, as shown by FIG. 8E, a Ru film with a thickness of 40 nm, a TiO₂ film with a thickness of 17 nm, a Ta₂O₅ film with a thickness of 13 nm and a Ru film with a thickness of 40 nm are deposited sequentially, and an MIM structure including the lower electrode 1, the insulation layer (resistance change layer) 2 and the upper electrode 3 is formed by an exposure process and a dry-etching process. A DC sputtering method is used for the deposition of Ru. A reactive sputtering method using a DC sputtering equipment is used for the deposition of TiO₂. A sputtering target is Ti and a flow ratio of an O₂ gas and Ar gas is 1:5. The pressure in a chamber is 10 mTorr, the temperature for film formation is set to 300° C. and power is 4.2 kW. An RF sputtering method is used for the deposition of Ta₂O₅. Ta₂O₅ is used for a sputtering target and 10 sccm of O₂ gas and 5 sccm of Ar gas are flown. The temperature for film formation is set to 350° C. and power is 2 kW.

Next, as shown by FIG. 8F, a second interlayer insulation film 14 is deposited on the entire surface of the semiconductor substrate 15 and a surface of the second interlayer insulation film 14 is flattened by a CMP method. An oxide film is used for the second interlayer insulation film 14 in the present example.

Next, the second interlayer insulation film 14 and the first interlayer insulation film 13 are exposed and dry-etched to open a via and TiN and W are deposited.

As shown by FIG. 8G, the surface is flattened by CMP and the TiN and W other than the via portions are removed to form the vias 9 and 10.

Next, TiN and Al (aluminum) are deposited sequentially on the second interlayer insulation film 14 to form a metal interconnect layer, and the layer is exposed and dry-etched for patterning to form the first and the second interconnect layers 11 and 12.

According to the present example, a switching operation with small variation can be realized because when applying a Forming voltage or switching from a high resistance state to a low resistance state, a current can be controlled by the gate electrode 5 of the control transistor by connecting the MIM device of the resistance change type non-volatile memory with the source/drain 6 and 7 of the control transistor.

### Example 2

Alternative example will be described in which a semiconductor device of the present invention is applied to a 1T1R (one-transistor and one-resistor) type ReRAM.

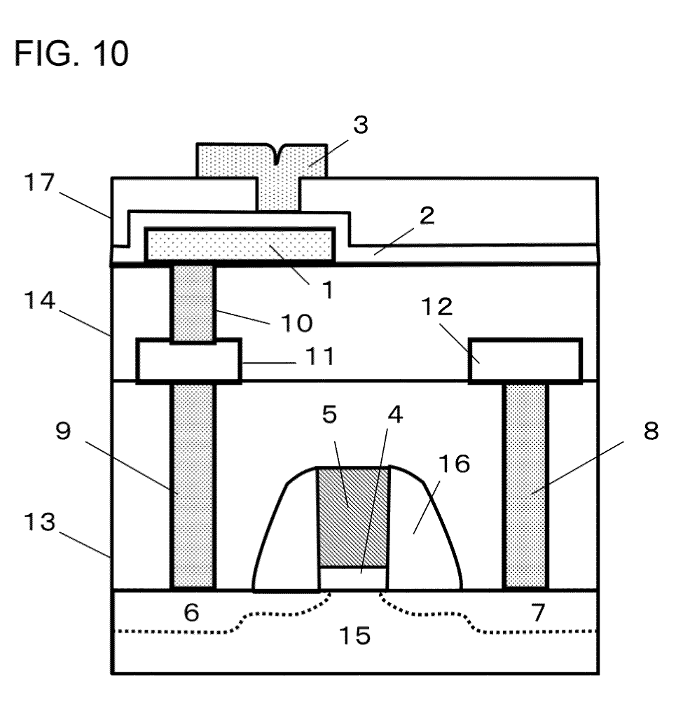

FIG. 10 shows a sectional view of a 1T1R (one-transistor and one-resistor) type ReRAM which comprises a semiconductor device of the present invention. Referring to FIG. 10, a control transistor including a gate insulation film 4, gate electrode 5, gate side wall 16 and source/drain 6 and 7 is formed on the semiconductor substrate 15. A via 9 is formed so as to connect to the source/drain 6, and a first interconnect layer 11 (interconnect formed by patterning an interconnect layer) is formed so as to connect to the via 9. A via 8 is formed so as to connect to the source/drain 7, and a second interconnect layer 12 is formed so as to connect to the via 8. A via 10 is formed so as to contact with the first interconnect layer 11, and a lower electrode 1 is formed so as to connect to the via 10. An insulation layer (resistance change layer) 2 of a laminated film including a Ta₂O₅ film and a TiO₂ film with a thickness of less than 30 nm and a third interlayer insulation film 17 are formed on the lower electrode 1, and an upper electrode 3 is embedded in an opening of the third interlayer insulation film 17 and contacted with the insulation layer 2.

According to the present example, the upper electrode 3 is formed smaller than the lower electrode 1, and thus an area of the MIM structure is limited by a contacting area of the upper electrode 3 with the insulation layer (resistance change layer) 2.

In the present example, a NMOS is used as the control transistor and a laminated structure as the ReRAM module including an upper electrode (T.E.:Pt)/a Ta₂O₅ film (10 nm in thickness)/a TiO₂ film (3 nm in thickness)/a lower electrode (B.E.:Ru) is used.

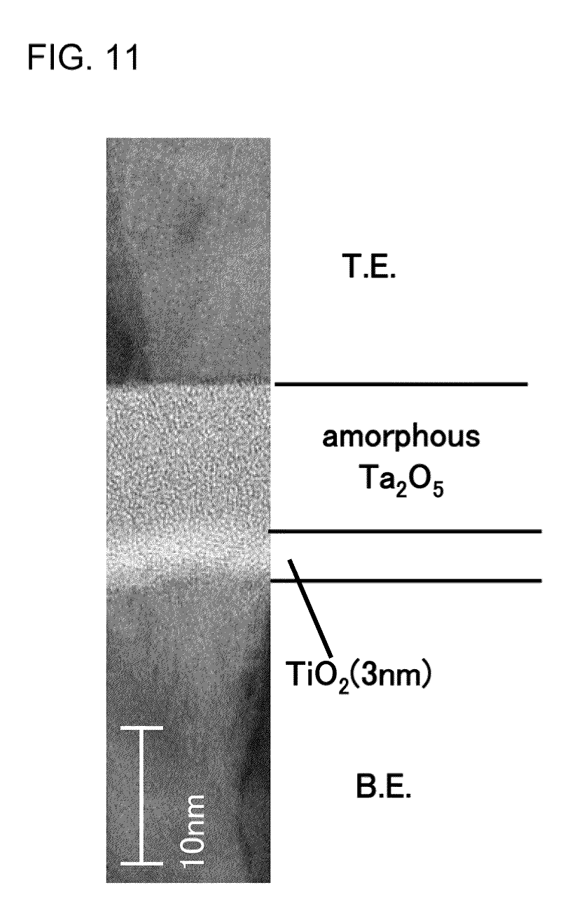

FIG. 11 shows a sectional TEM (Transmission Electron microscope) image of the MIM portion of the 1T1R-ReRAM of the present example. The Ta₂O₅ layer is amorphous and the interface of the layer between the upper electrode (T.E.) is extremely flat. The thickness of the TiO₂ layer is 3 nm and the thickness of the Ta₂O₅ layer is 10 nm.

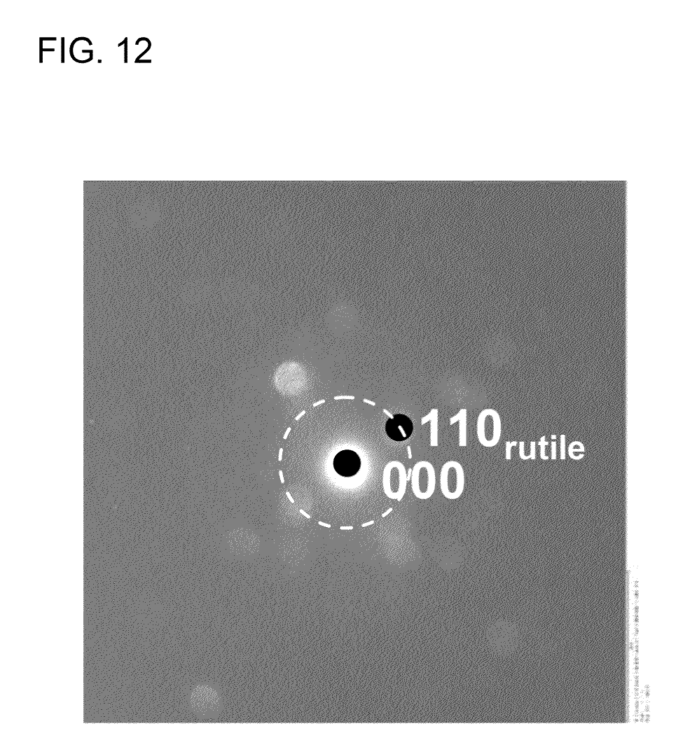

FIG. 12 shows a nano-beam diffraction image of the TiO₂ layer of FIG. 11. A position of the spot appeared by the nano-beam diffraction of the TiO₂ layer is coincident with a position of 110 diffraction of the Rutile Structure shown by a dotted line.

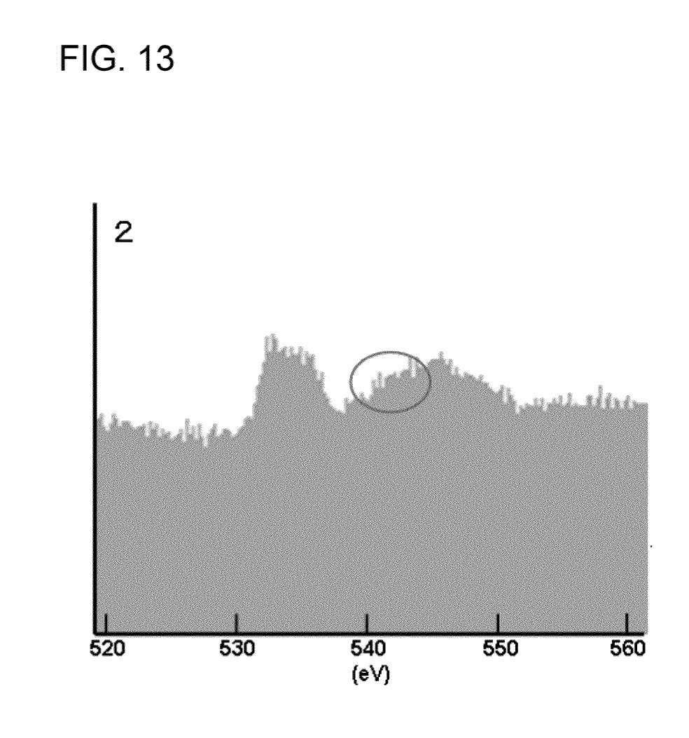

FIG. 13 shows an analysis result of an EELS (Electron Energy Loss Spectroscopy) of the TiO₂ layer of FIG. 11. Spectrum around K-edge of oxygen is shown. Because no distinctive spectrum shape is seen in an energy range shown by a circle in FIG. 13, the EELS result also supports that the TiO₂ layer has a Rutile Structure.

Thus it has been found that the TiO₂ layer of the MIM portion of the 1T1R-ReRAM formed in accordance with the present invention has a Rutile structure.

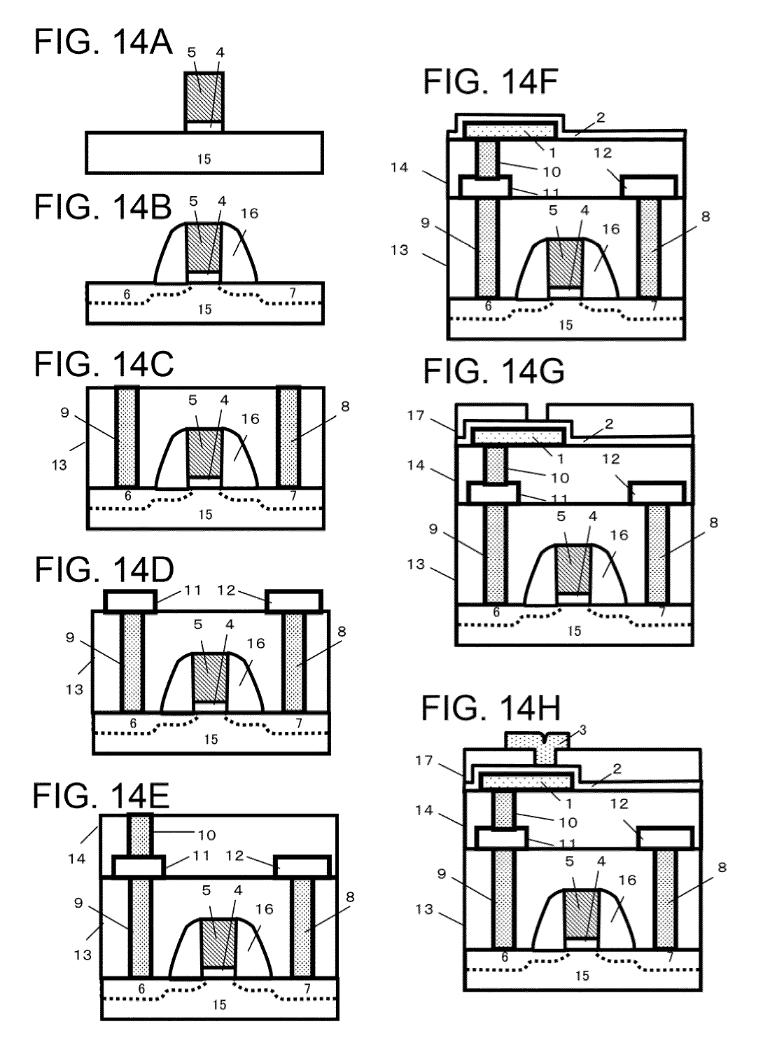

A fabrication method of the present example will be described with reference to sectional process diagrams in FIG. 14. As shown in FIG. 14A, a gate oxide film 4 and a phosphorous-doped poly-silicon 5 are deposited on a semiconductor substrate 15, and then they are exposed and dry-etched for patterning to form a gate electrode 5.

Next, as shown in FIG. 14B, gate side walls 16 are formed by an insulation film deposition process and a dry etch-back process. Source/drain regions 6 and 7 are formed by doping phosphor with a dose of 2E+15 cm⁻² using the gate electrode 5 and the gate side walls 16 as a mask.

Next, as shown in FIG. 14C, a first interlayer insulation film 13 is deposited on an entire surface of the semiconductor substrate 15 and the surface of the film is flattened by CMP. An oxide film is used for the first interlayer insulation film 13 in the present example.

Next, the first interlayer insulation film 13 is exposed and dry-etched to perforate the film to make vias, and TiN (titanium nitride) and W (tungsten) are deposited.

The surface is flattened by CMP and the deposited TiN and W portion other than via portions is eliminated to form vias 8 and 9.

Next, as shown in FIG. 14D, TIN and Al (aluminum) are deposited in this order to form a metal interconnect layer and the layer is exposed and dry-etched for patterning to form a first and a second interconnect layers 11 and 12.

Next, as shown in FIG. 14E, a second interlayer insulation film 14 is deposited on an entire surface of the semiconductor substrate 15 and the surface of the second interlayer insulation film is flattened by CMP. An oxide film is used for the second interlayer insulation film 14 in the present example. Next, the second interlayer insulation film 14 is exposed and dry-etched to perforate the film to make a via, and TiN (titanium nitride) and W (tungsten) are deposited. The surface is flattened by CMP and the deposited TiN and W portion other than via portion is removed to form via 10.

Next, as shown in FIG. 14F, a Ru film of 40 nm thickness is deposited and the Ru film is exposed and dry-etched to form a lower electrode 1.

Next, a TiO₂ film of 3 nm thickness and a Ta₂O₅ film of 10 nm thickness are deposited sequentially to form an insulation layer (resistance change layer) 2.

Next, as shown in FIG. 14G, a third interlayer insulation film 17 is deposited on an entire surface of the semiconductor substrate 15 and the surface of the third interlayer insulation film is flattened by CMP. An oxide film is used for the third interlayer insulation film 17 in the present example. Next, the third interlayer insulation film 17 on the lower electrode 1 is exposed and dry-etched to form an opening.

Next, as shown in FIG. 14H, a Ru film of 40 nm thickness is deposited and the Ru film is exposed and dry-etched to form an upper electrode 3.

An area of the MIM structure is limited by a contacting area of the upper electrode 3 with the resistance change layer 2.

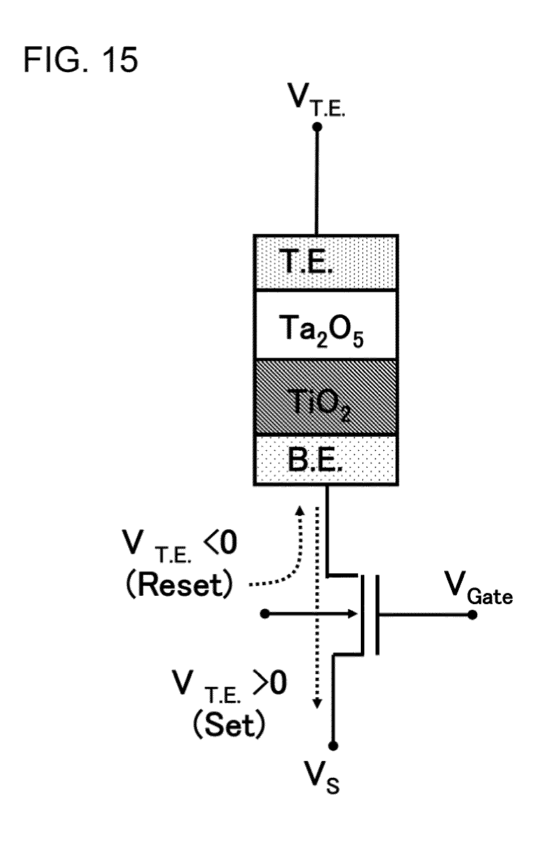

FIG. 15 is a diagram explaining an operation after Forming in the present example.

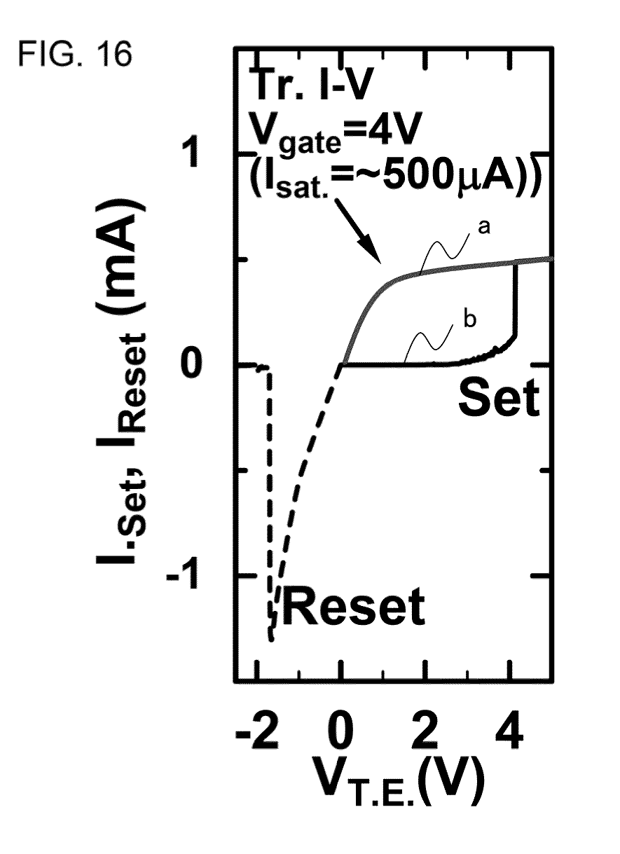

FIG. 16 is a graph indicating a relation between I and V_{T.E.} at time points of Set (switching time from a high resistance state to a low resistance state) and Reset (switching time from a low resistance state to a high resistance state).

As shown in FIG. 16, at a Set time, a positive voltage (V_{T.E.}) is applied on the upper electrode (T.E.) to control a Set level (R_{L}) with a saturated current (Iₛₐₜ) of the control transistor. In FIG. 16, the characteristic curve “a” indicates a ID (a drain current)−V_{T.E.} characteristic of the control transistor with VGATE=4V.

As is shown by the characteristic curve “b”, although an abrupt increase of a current occurs around a voltage of V_{T.E.}=4V caused by lowering of a resistance of the ReRAM, an increase of the current is limited by a saturated current of the control transistor. When erasing, a negative voltage is applied on the upper electrode. At this time, the current is not limited by the control transistor and caused to flow between the upper electrode and a P-well. The erasing can be carried out by applying a positive voltage on both the second interconnect layer 12 and the gate electrode 5.

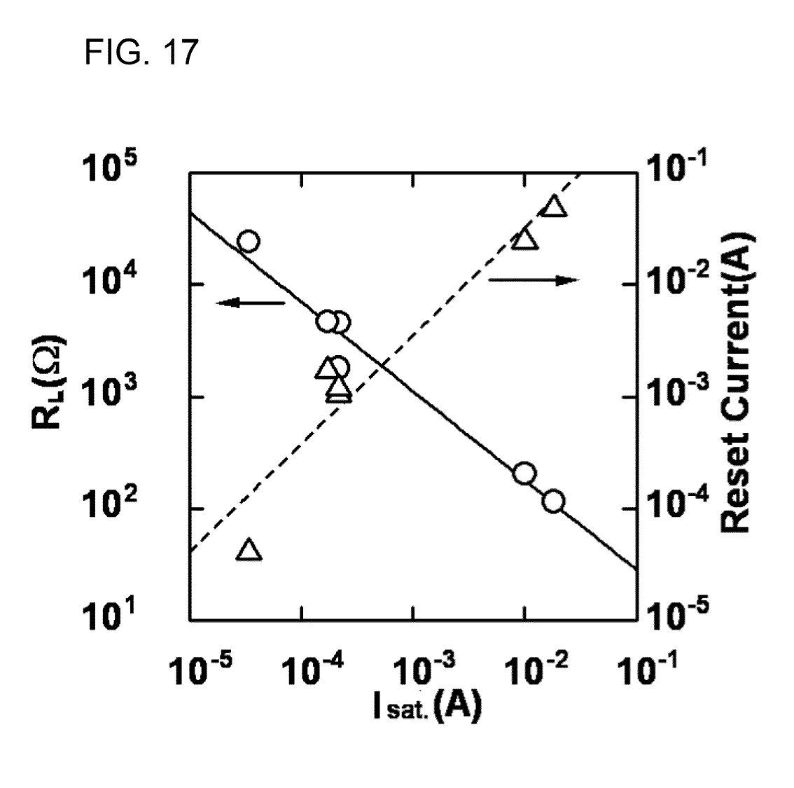

FIG. 17 shows a relation between a saturated current of the control transistor (I_{sat.}) and a Set level (R_{L}) and a Reset current and a relation between a Reset current and 1/R_{L}.

As shown by a solid line in FIG. 17, R₁ can be controlled by controlling I_{sat.} by V_{GATE}.

As shown by a dotted line in FIG. 17, when R_{L} is controlled by I_{sat.}, the Reset current is controlled and the Reset current is proportionate to 1/R_{L}.

It is supposed that the reason is that the Reset mechanism (positive pole oxidation of a filament near the lower electrode) is controlled by an electric field in the Ta₂O₅/TiO₂

Table 3 shows operation conditions of Read, Set and Reset (where V_{T.E.} is a voltage of the upper electrode, V_{Gate} is a gate voltage, Vₛ is a substrate voltage and V_{well} is a well voltage).

A saturated current of the control transistor at a Set time is set to 150 μA (V_{Gate}=2.5V). A verification (Verify) by an additional write is performed for the Set.

The R_{L} (Typical) at this time is 1.7 kΩ.

A Reset current is slightly less than 1 mA, which is larger than a target value (200 μA or less).

A voltage applied on the upper electrode (V_{T.E.}) at a Read time is 0.06 V.

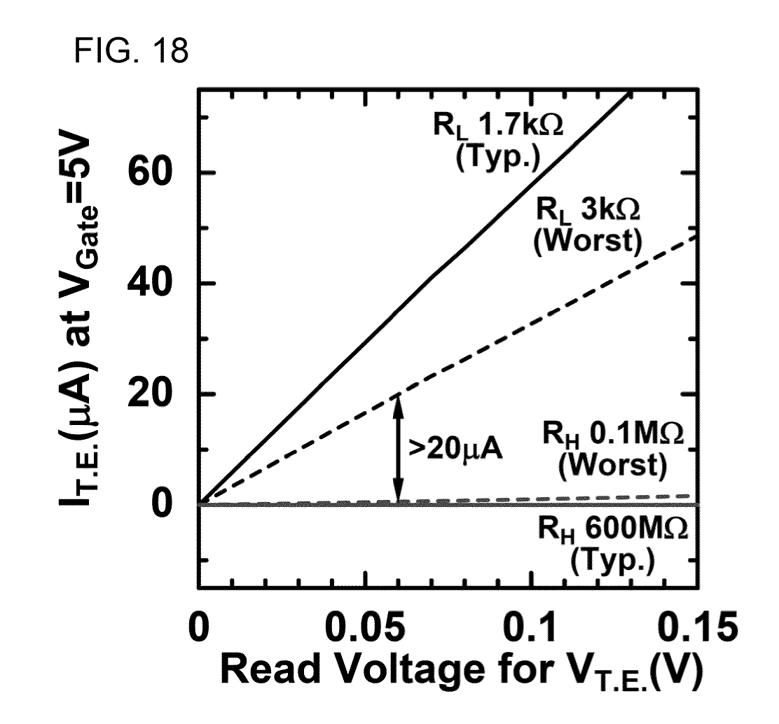

FIG. 18 is a diagram of a curve (characteristic) of I_{READ}-V_{T.E.} at a Read time. The vertical axis is a current of the upper electrode I_{T.E.} at a Read time under the voltage of V_{Gate}=5 V, and the horizontal axis is a voltage of the upper electrode V_{T.E.} at a Read time (Read Voltage for V_{T.E.}). There are plotted characteristics for the resistance in a high resistance state with R_{H}=600 MΩ (solid line, typical example) and R_{H}=0.1 MΩ (broken line, worst case example), and the resistance in a low resistance state with R_{L}=1.7 kΩ (solid line, typical example) and R_{L}=3 kΩ (broken line, worst case example).

Assuming a NOR-type configuration with a read speed of 100 MHz, 20 μA of difference of Read current is necessary between Set time and Reset time. Assuming that the voltage V_{T.E.} of the upper electrode at Read time is 0.06 V, the R_{L} should be 3 kΩ or less and the R_{H} should be 0.1 MΩ or more. A difference between the typical R_{L} (1.7 kΩ) and R_{H} (60 MΩ) and a criteria value (Criteria) described before becomes a margin for a disturbance or variation.

TABLE 3

| | V_{T.E.} | V_{Gate} | V_{S}, V_{WELL} |
|---|---|---|---|
| Read | 0.06 V | 5 V | 0 V |
| Set (Verify) | 5 V | 2.5 V (I_{sat.} = 150 μA) | 0 V |
| Reset | −2.5 V | 0 V | 0 V |

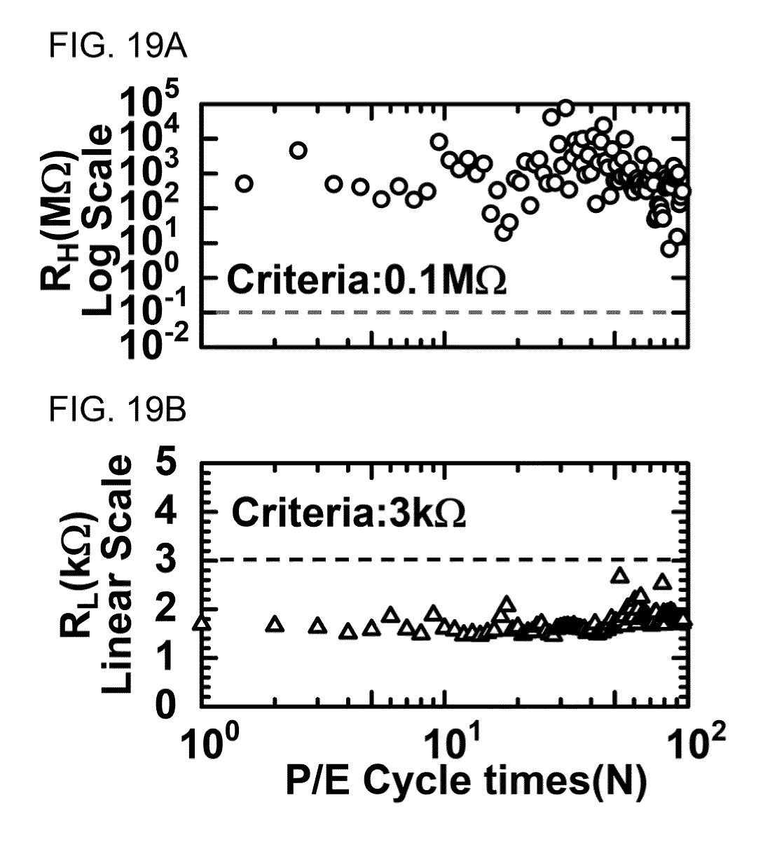

FIGS. 19A and 19B show dependences of R_{H} and R_{L} on a number of rewriting. A sweep method is used for Set and a pulse of 200 μsec is used for Reset. A vertical axis R_{H} of FIG. 19A is a logarithmic scale and A vertical axis R_{L} of FIG. 19B is a linear scale. The horizontal axes of FIGS. 19A and 19B indicate rewriting times (number of P/E cycles). Both of the R_{H} and R_{L}, are within the criteria. Particularly, the variation of the R_{L} caused by rewriting could be controlled very small by using the control transistor.

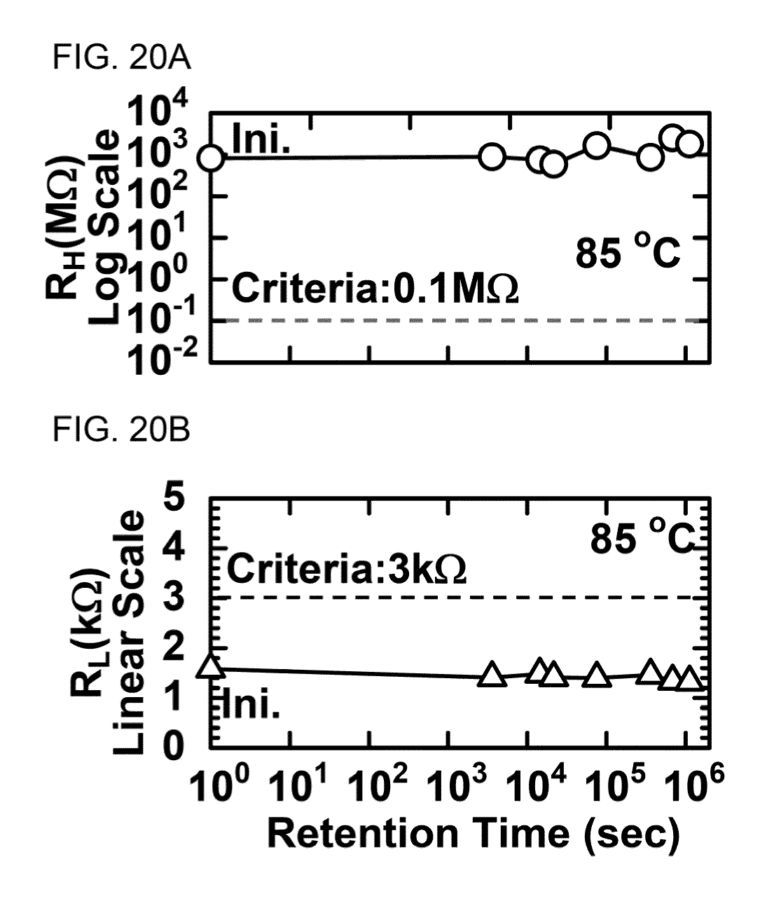

FIGS. 20A and 20B show test results of retention (data holding) under temperature at 85° C. The vertical axis R_{H} of FIG. 20A is a logarithmic scale and the vertical axis R_{L} of FIG. 20B is a linear scale. The horizontal axes of FIGS. 20A and 20b indicate retention time (unit: second). As shown in FIGS. 20A and 20B, it have been found that both R_{H} and R_{L} did not deviate much in the retention time (100 to 106 seconds) and had a high reliability.

Next, an evaluation of a Read disturbance tolerance is performed. Stress conditions are so set as VG=5 V and V_{T.E.}=0.1 to 1.5 V at a room temperature.

FIGS. 21A and 21B show temporal variations of R_{H} and R_{L} under application of a stress voltage of 0.1 V (60 μA) as V_{T.E.} The number of P/E (program and erase) is two.

As shown in FIGS. 21A and 21B, both R_{H} and R_{L} showed almost no variation under a stress voltage as large as 1.6 times of the Read voltage.

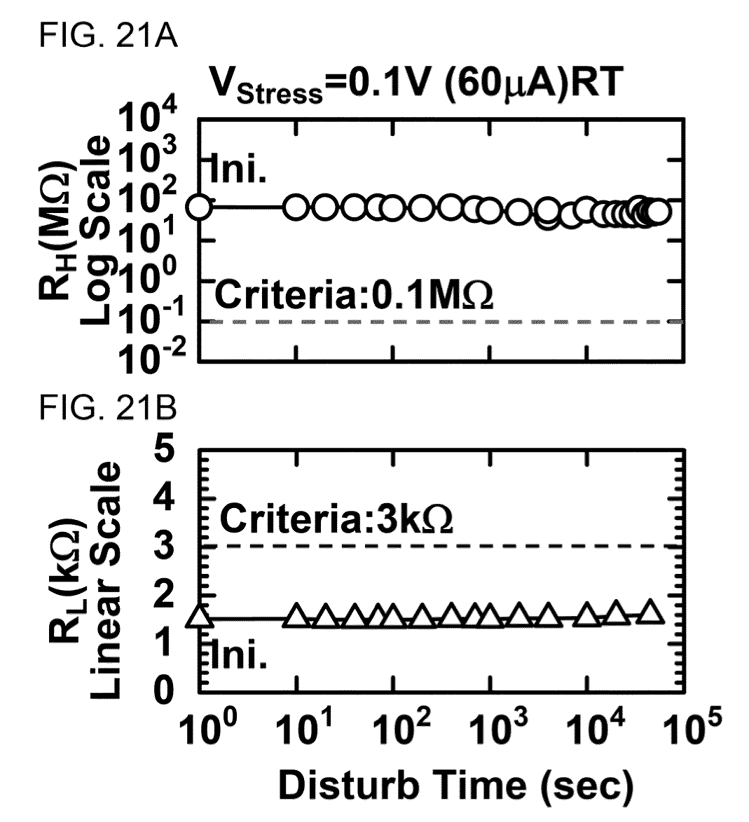

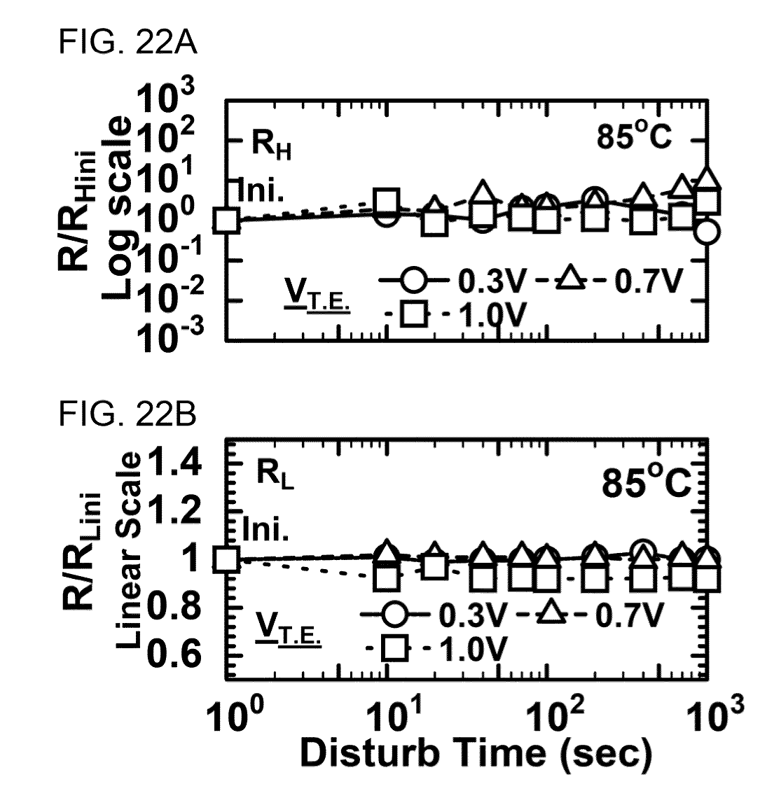

FIGS. 22A and 22B show variation rates of R_{L} and R_{H} (R/R_{Lini}, R/R_{Hini}) under a high voltage stress which ranges from 1.6 times (0.1 V) to 16 times at a maximum (1.0 V) of the Read voltage. The R_{Lini} is an initial resistance of the R_{L} and the R_{Hini} is an initial resistance of the R_{H}. The “Ini.” in FIGS. 22A and 22B indicate an initial resistance of R_{H} or R_{L}. A vertical axis of FIG. 22A is R/R_{Hini} in logarithmic scale and a vertical axis of FIG. 22B is R/R_{Lini} in a linear scale. Horizontal axes of FIGS. 22A and 22B are disturbance time (second). In FIGS. 22A and 22B, the symbols “∘”, “Δ” and “□” indicate variation rates of R_{L} and R_{H} under conditions of V_{T.E.}=0.3 V, V_{T.E.}=0.7 V and V_{T.E.}=1.0 V, respectively.

Even when a voltage which is 25 times as large as the Read voltage is applied, the variation rate of R_{L} (R/R_{Lini}) is 8% or less as shown in FIG. 22B, and the variation rate of R_{H} (R/R_{Hini}) is two times or less as shown in FIG. 22A. Thus it has been found that the semiconductor device has an extremely high tolerance against disturbance.

Particularly, the reason why an increase f the resistance of R_{L}, a margin of which is strict, can be suppressed is that an anode oxidation around the interface between the upper electrode and the Ta₂O₅ film is completely eliminated by introduction of a Ta₂O₅/TiO₂ laminated film according to the present invention.

### Example 3

Next, a ReRAM as a semiconductor device of a third example (Example 3) of the present invention will be described. According to the present example, a lower electrode of the ReRAM is formed by a laminated structure including TaN and Ru or TaN and Pt.

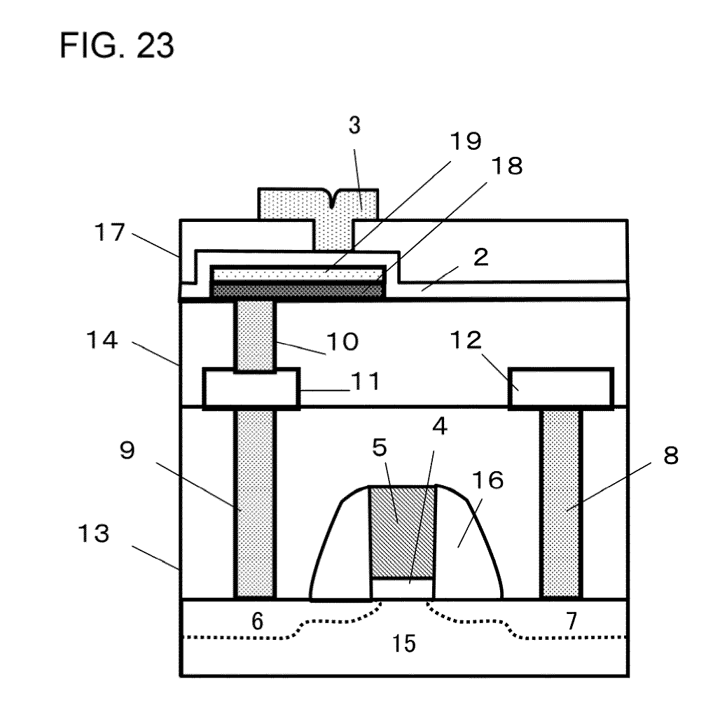

FIG. 23 illustrates a cross-sectional view in which a semiconductor device of the present invention is applied to a one-transistor and one-resistor type ReRAM. Referring to FIG. 23, a control transistor including a gate insulation film 4, a gate electrode 5, gate side walls 16 and source/drain 6 and 7 is formed on a semiconductor substrate 15. A via 9 is formed so as to connect to the source/drain 6.

A first interconnect layer 11 (interconnect formed by patterning an interconnect layer) is formed so as to connect to the via 9. A via 8 is formed so as to contact with the source/drain 7, and a second interconnect layer 12 is formed so as to connect to the via 8.

A via 10 is formed so as to contact with the first interconnect layer 11, and a TaN layer 18 that is to be a lower layer of a lower electrode is formed so as to connect to the via 10. A Ru layer 19 that is to be an upper layer of the lower electrode is formed on the TaN layer 18.

An insulation layer (resistance change layer) 2 of a laminated film including a Ta₂O₅ film and a TiO₂ film with a thickness of less than 30 nm and a third interlayer film 17 are formed on the Ru layer 19.

An upper electrode 3 is embedded in an opening of the third interlayer film 17 so as to contact with the insulation layer (resistance change layer) 2. Ru is used for the upper electrode 3.

According to the present example, the upper electrode 3 is formed smaller than the lower electrode layer including the TaN layer 18 and the Ru layer 19, and thus an area of the MIM structure is limited by a contacting area of the upper electrode 3 with the resistance change layer 2.

In an Example 3, a NMOS is used as the control transistor and a laminated structure as the ReRAM module is including: upper electrode (T.E.:Ru)/Ta₂O₅ film (10 nm in thickness)/TiO₂ film (3 nm in thickness)/lower electrode (B.E.:Ru/TaN laminated film).

An effect of the lower electrode including a laminated film of the Ru and TaN will be described by comparing with a sample having a Ru single layer without TaN layer as a lower electrode.

The TaN layer 18 has an effect to suppress diffusion of metals as impurities from a layer arranged below the ReRAM module to the ReRAM layer.

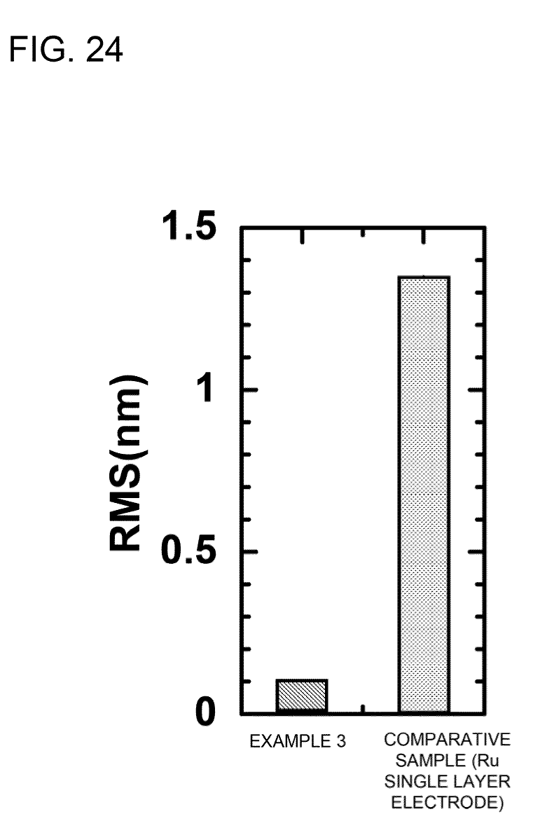

FIG. 24 shows roughness of lower electrodes of Example 3 of the present invention and that of a comparative example (having a single film of Ru) measured by an AFM (Atmic Force Microscope).

As shown in FIG. 24, the roughness value (RMS: Root Mean Square) of the lower electrode of an Example 3 decreased one tenth or less of that of the comparative example by causing the lower electrode to have a laminated structure including the Ru layer 19 and TaN layer 18 as shown in FIG. 23.

The laminated structure including Ru and TaN is used as the lower electrode in the present example. However, the same effect is obtained when a laminated structure including Pt and TaN is used.

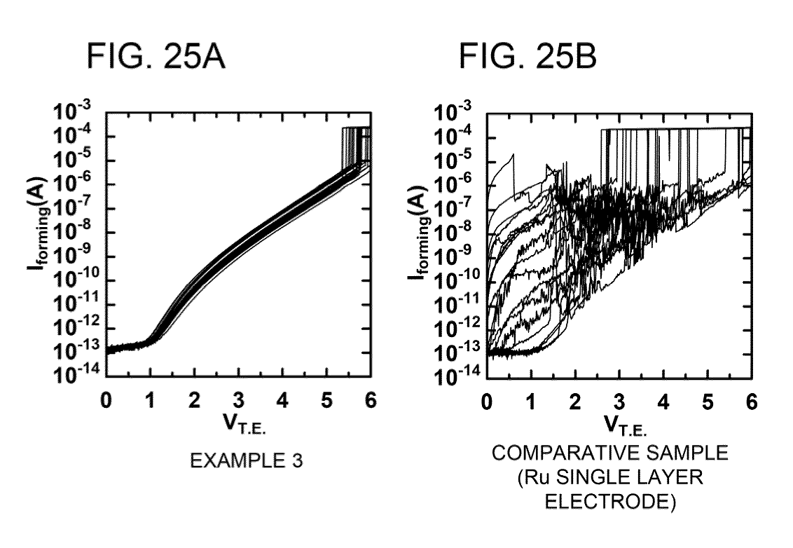

FIG. 25A shows a characteristic of current (I)−voltage (V_{T.E.}) applied on the upper electrode at Forming in Example 3 of the present invention. The results of 26 samples are superposed.

As shown in FIG. 25A, the differences or variations of curves of I−V_{T.E.} obtained by the samples of an Example 3 are small. On the other hand, as shown in FIG. 25B, the variations of curves of I−V_{T.E.} obtained by comparative samples (single layer structure including Ru) are extremely large. The result is due to a local concentration of electric field and a formation of an abnormal filament caused by the roughness of the interface of the lower electrode.

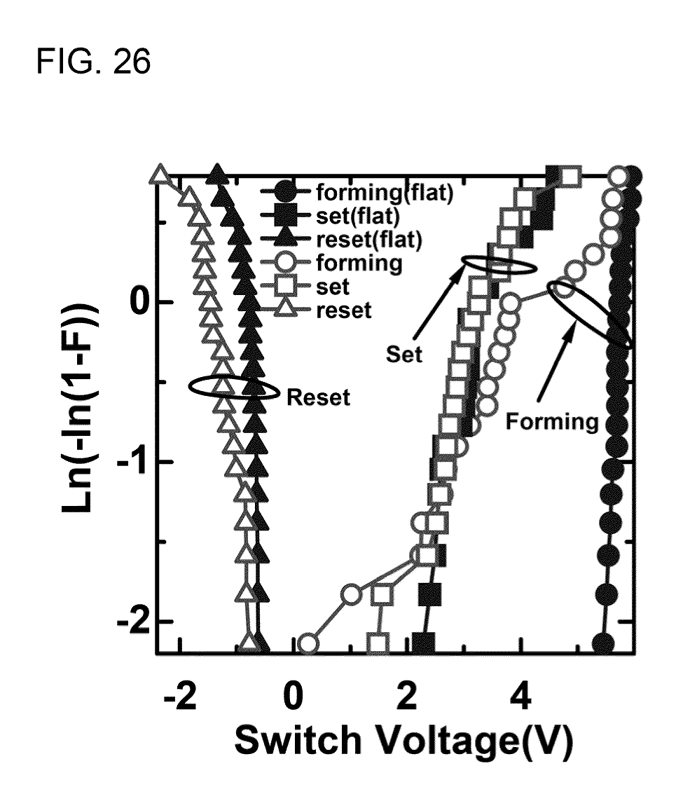

FIG. 26 shows Weibull plots of a Forming voltage, Set voltage and Reset voltage of Example 3 of the present invention and a comparative example (Ru single layer electrode). In FIG. 26, a black circle (circle filled with black) (), a black square (▪) and a black triangle (▴) are the Forming voltage distribution, Set voltage distribution and Reset voltage distribution, respectively, of Example 3 of the present invention, and the solid-white circle (∘), solid-white square (□) and solid-white triangle (Δ) are the Forming voltage distribution, Set voltage distribution and Reset voltage distribution, respectively, of a comparative example (Ru single layer sample).

As shown in FIG. 26, it has been found that the variation of the Forming voltage is much improved by introducing the Ru/TaN laminated structure for the lower electrode. The Set voltage distribution and the Reset voltage distribution are not so improved.

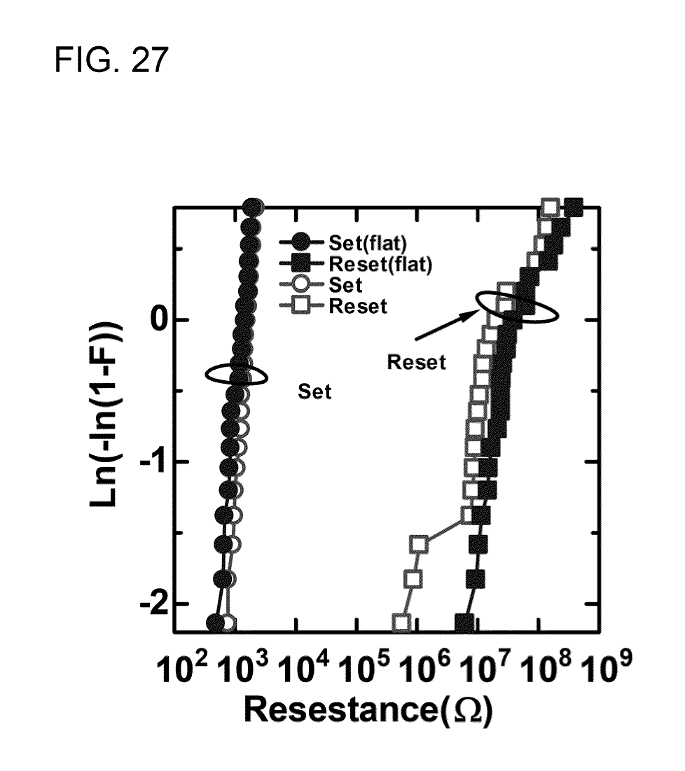

FIG. 27 shows Weibull plots of a resistance after Set and resistance after Reset of Example 3 of the present invention and a comparative example of the Ru single layer electrode. In FIG. 27, a black circle () and black square (▪) are the resistance distribution after Set and the resistance distribution after Reset, respectively, of an Example 3 of the present invention, and a solid-white circle (∘) and solid-white square (□) are the resistance distribution after. Set and the resistance distribution after Reset, respectively, of a comparative sample (Ru single layer structure).

As shown in FIG. 27, both of the resistance distributions after Set are almost the same; however, it has been found that a part of the resistance distribution after Reset of a comparative sample deviated to low resistance side.

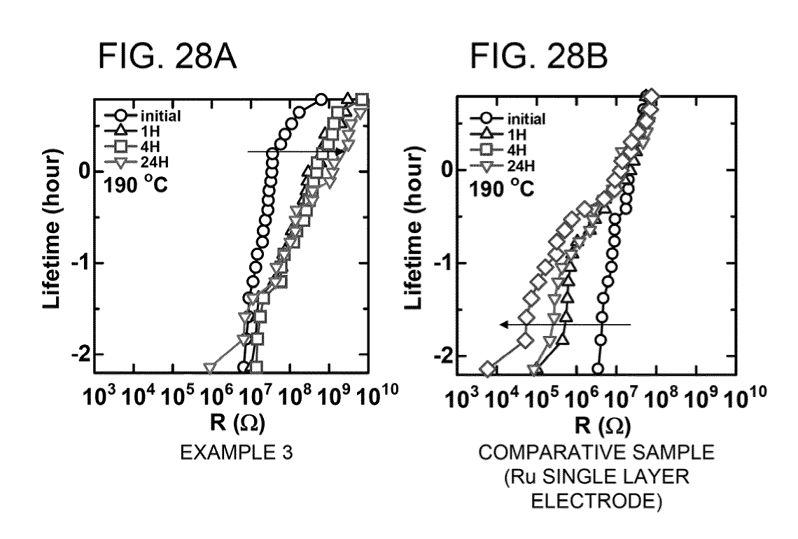

FIGS. 28A and 28B are diagrams of changes of resistance distributions after Reset under a high-temperature stress at 190° C. of Example 3 of the present invention and a sample of a comparative example (Ru single layer electrode).

In FIG. 28, the solid-white circle (∘), solid-white triangle (Δ), solid-white square (□) and solid-white inverted triangle (∇) indicate values of resistance at initial state, after one hour, after four hours and after 24 hours, respectively. As shown in FIG. 28, it is ascertained that a comparative sample may malfunction by the high temperature stress at 190° C. because the resistance of a part of the comparative samples shifted to the Set resistance side and therefore it became impossible to distinguish from the Set state in a short time.

On the other hand, the semiconductor device according to Example 3 of the present invention has been found to be more reliable because the shift of the resistance to a low resistance side is small, rather shifts to a high resistance side.

As described above, it has been found that, according to the present invention, diffusion of metal impurities and roughness of the interface of the lower electrode are improved and thus deviation of the Forming voltage and sustainable-reliability at a high temperature are improved by causing the lower electrode to have a laminated structure including Ru and TaN. The same effect is also obtained by making the lower electrode as a laminated structure including Pt and TaN.

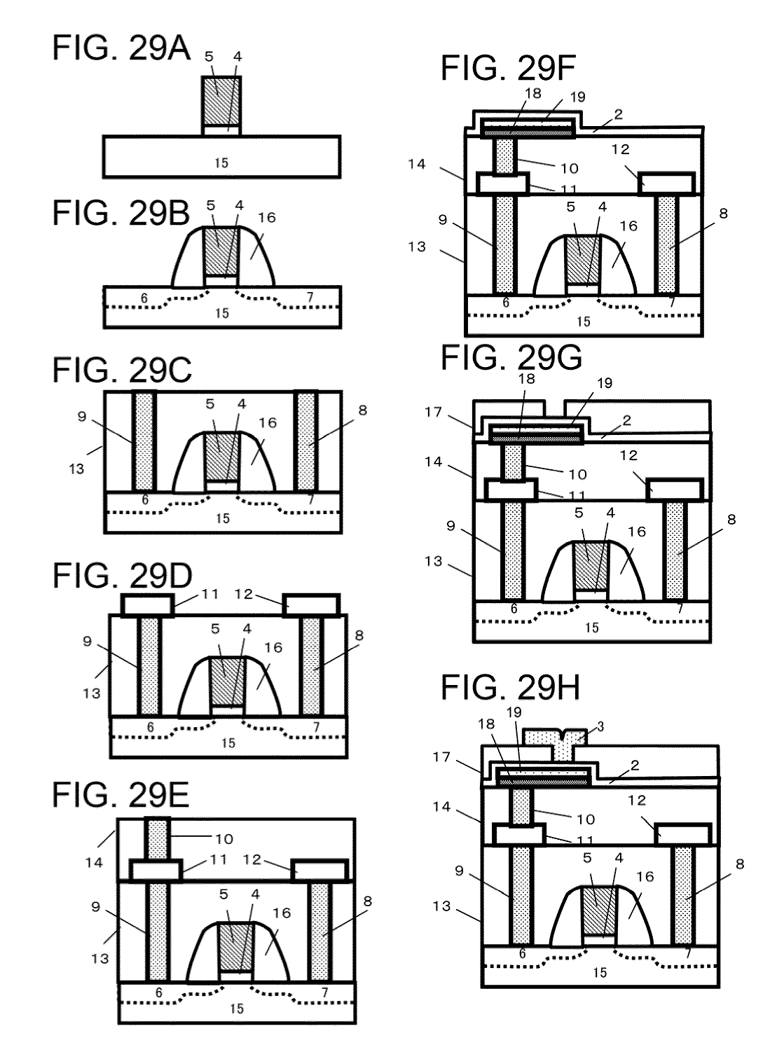

A manufacturing method of Example 3 of the present invention will be described with reference to sectional process diagrams of FIG. 29.

At first, as shown in FIG. 29A, a gate oxide film 4 and a phosphorous-doped polysilicone 5 are deposited on a semiconductor substrate 15, and then they are exposed and dry-etched for patterning to form a gate electrode 5.

Next, as shown in FIG. 29B, gate side walls 16 are formed by an insulation film deposition process and a dry etch-back process. Source/drain regions 6 and 7 are formed by doping phosphor with a dose of 2E+15 cm⁻² using the gate electrode 5 and the gate side walls 16 as a mask.

Next, as shown in FIG. 29C, a first interlayer insulation film 13 is deposited on an entire surface of the semiconductor substrate 15 and the surface of the film is flattened by CMP. An oxide film is used for the first interlayer insulation film 13 in the present example.

Next, the first interlayer insulation film 13 is exposed and dry-etched to perforate the film to make vias, and TiN (titanium nitride) and W (tungsten) are deposited.

The surface is flattened by CMP and the deposited TiN and W portion other than via portions is eliminated to form vias 8 and 9.

Next, as shown in FIG. 29D, TiN and Al (aluminum) are deposited in this order to form a metal interconnect layer and the layer is exposed and dry-etched for patterning to form a first and a second interconnect layers 11 and 12.

Next, as shown in FIG. 29E, a second interlayer insulation film 14 is deposited on an entire surface of the semiconductor substrate 15 and a surface of the second interlayer insulation film is flattened by CMP. An oxide film is used for the second interlayer insulation film 14 in the present example.

Next, the second interlayer insulation film 14 is exposed and dry-etched to perforate the film to make a via, and TiN (titanium nitride) and W (tungsten) are deposited. The surface is flattened by CMP and the deposited TiN and W portion other than via portion is removed to form via 10.

Next, as shown in FIG. 29F, a TaN layer 18 of 20 nm thickness and a Ru layer 19 of 40 nm thickness are deposited and the layers are exposed and dry-etched to form a lower electrode (laminated structure including the TaN layer 18 and the Ru layer 19).

Next, a TiO₂ film of 3 nm thickness and a Ta₂O₅ film of 10 nm thickness are deposited sequentially to form an insulation layer (resistance change layer) 2.

Next, as shown in FIG. 29G, a third interlayer insulation film 17 is deposited on an entire surface of the semiconductor substrate 15 and the surface of the third interlayer insulation film is flattened by CMP. An oxide film is used for the third interlayer insulation film 17 in the present example. Next, the third interlayer insulation film 17 on the lower electrode 1 is exposed and dry-etched to form an opening up to the insulation layer (resistance change layer) 2.

Next, as shown in FIG. 29H, a Ru film of 40 nm thickness is deposited and the Ru film is exposed and dry-etched to form an upper electrode 3.

An area of the MIM structure is limited by a contacting area of the upper electrode 3 with the resistance change layer 2.

### Example 4

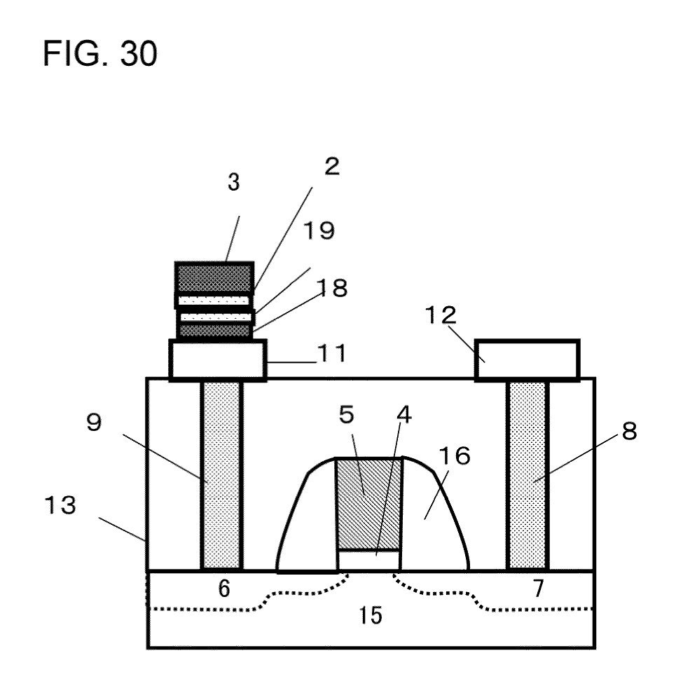

Next, a fourth example (Example 4) of the present invention will be described. An MIM structure including a ReRAM is directly formed on a lower wiring in the present example. FIG. 30 shows a schematic view of a sectional configuration in which a semiconductor device according to the present invention is applied to 1T1R (one-transistor and one-resistor) type ReRAM.

Referring to FIG. 30, a control transistor including a gate insulation film 4, a gate electrode 5, gate side walls 16 and source/drain 6 and 7 is formed on a semiconductor substrate 15. A via 9 is formed so as to connect to the source/drain 6.

A first interconnect layer II (patterned lines formed on an interconnect layer) is formed so as to connect to the via 9. A via 8 is formed so as to connect to the source/drain 7, and a second interconnect layer 12 is formed so as to connect to the via 8.

A TaN layer 18 which is to be a lower layer of a lower electrode is formed so as to connect to the first interconnect layer 11.

A Ru layer 19 which is to be an upper layer of the lower electrode is formed on the TaN layer 18. An insulation layer 2 having a laminated structure which includes a Ta₂O₅ film and a TiO₂ film with a thickness of less than 30 nm is formed on the Ru layer 19. An upper electrode 3 is formed on the insulation layer 2. Ru is used for the upper electrode in the present example.

In the present example, a NMOS is used as the control transistor and a laminated structure as the ReRAM module is including: an upper electrode (T.E.:Ru)/a Ta₂O₅ film (10 nm in thickness)/a TiO₂ film (3 nm in thickness)/a lower electrode (B.E.:Ru/TaN laminated). A laminated structure including Pt/TaN may be used for the lower electrode.

According to Example 4 of the present invention, the MIM portion of the ReRAM is directly formed on the lower electrode and hence a fabrication process can be greatly shortened and thus the fabrication cost can be reduced.

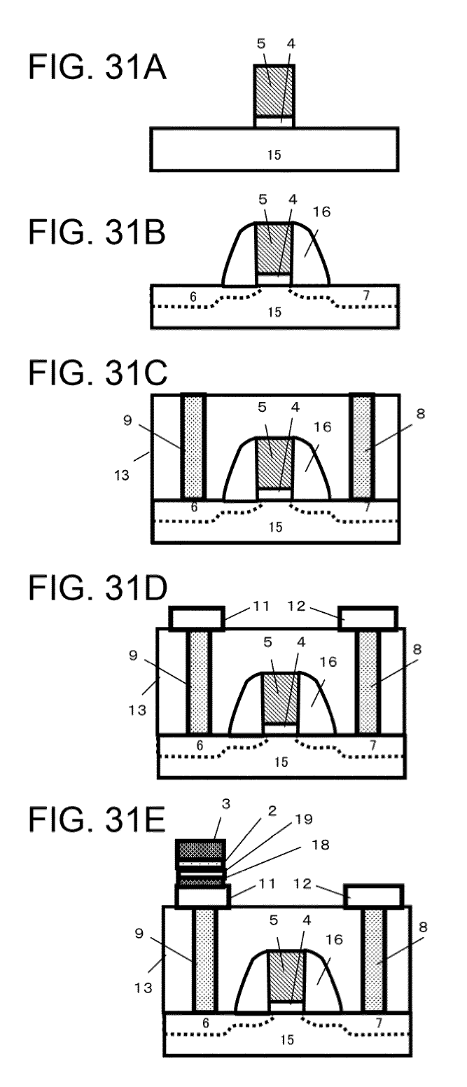

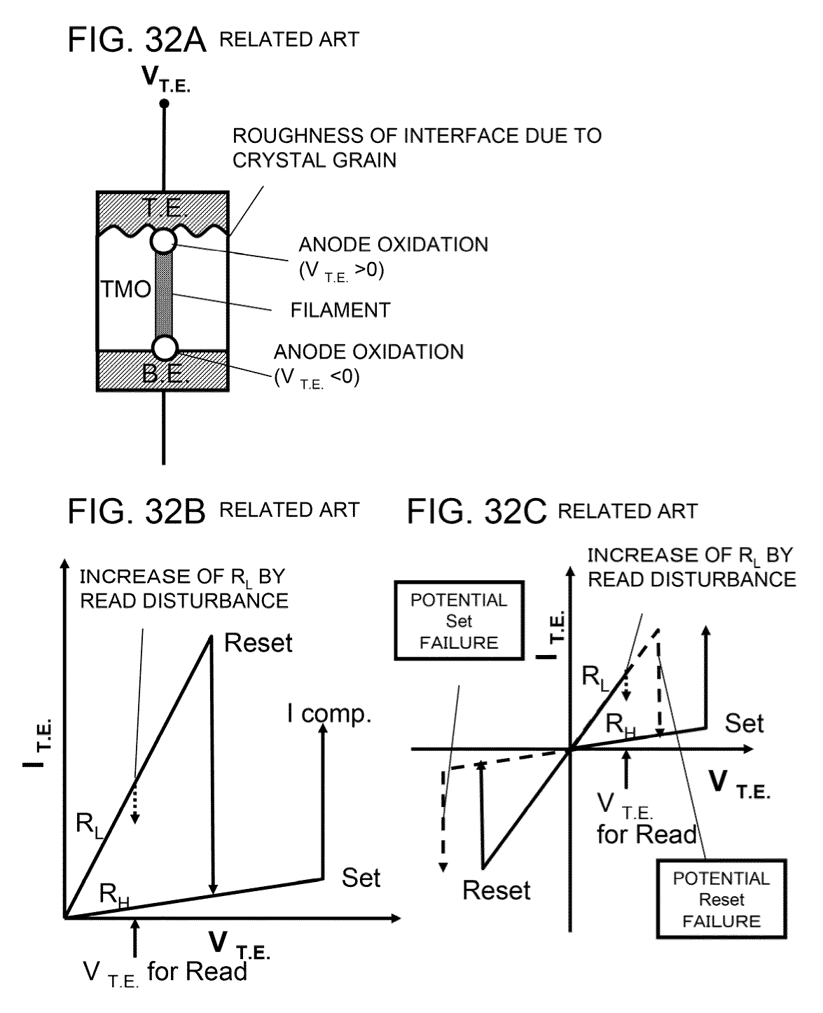

A fabrication method of Example 4 will be described with reference to sectional process diagrams of FIG. 31.

At first, as shown in FIG. 31A, a gate oxide film 4 and a phosphorous-doped polysilicone 5 are deposited on a semiconductor substrate 15, and then they are exposed and dry-etched for patterning to form a gate electrode 5.

Next, as shown in FIG. 31B, gate side walls 16 are formed by an insulation film deposition process and a dry etch-back process. Source/drain regions 6 and 7 are formed by doping phosphor with a dose of 2E+15 cm⁻², using the gate electrode 5 and the gate side walls 16 as masks.

Next, as shown in FIG. 31C, a first interlayer insulation film 13 is deposited on an entire surface of the semiconductor substrate 15 and the surface of the film is flattened by CMP. An oxide film is used for the first interlayer insulation film 13 in the present example.

Next, the first interlayer insulation film 13 is exposed and dry-etched to perforate the film to make vias, and TiN (titanium nitride) and W (tungsten) are deposited.

The surface is flattened by CMP and the deposited TiN and W portion other than via portions is eliminated to form vias 8 and 9.

Next, as shown in FIG. 31D, TiN and Al (aluminum) are deposited in this order to form a metal interconnect layer and the layer is exposed and dry-etched for patterning to form a first and a second interconnect layers 11 and 12.

Next, as shown in FIG. 31E, a TaN layer 18 of 20 nm thickness, a Ru layer 19 of 40 nm thickness, a TiO₂ film of 3 nm thickness and a Ta₂O₅ film of 10 nm thickness are deposited on the first interconnect layer 11 sequentially and the layers are exposed and dry-etched to form an MIM structure. The semiconductor device of an Example 4 of the present invention can be fabricated by the foregoing processes.

### Example 5

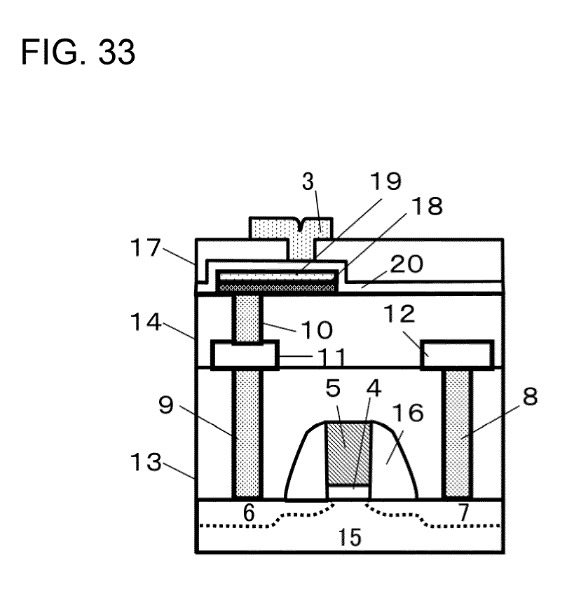

Next, a ReRAM semiconductor device according to a fifth example (Example 5) of the present invention will be described. According to this example, silicon is mixed in the Ta₂O₅ film of the ReRAM. FIG. 33 illustrates a sectional structure in which a semiconductor device according to the present invention is applied to 1T1R (one-transistor and one-resistor) type ReRAM.

Referring to FIG. 33, a control transistor including a gate insulation film 4, a gate electrode 5, gate side walls 16 and source/drain 6 and 7 is formed on a semiconductor substrate 15. A via 9 is formed so as to connect to the source/drain 6. A first interconnect layer 11 (patterned lines formed on an interconnect layer) is formed so as to connect to the via 9. A via 8 is formed so as to connect to the source/drain 7, and a second interconnect layer 12 is formed so as to connect to the via 8. A via 10 is formed so as to connect to the first interconnect layer 11, and a TaN layer 18 which is to be a lower layer of a lower electrode is formed so as to connect to the via 10. A Ru layer 19 which is to be an upper layer of the lower electrode is formed on the TaN layer 18. A resistance change layer 20 comprising a laminated film which includes a silicon-added Ta₂O₅ film and a TiO₂ film with a thickness of less than 30 nm and a third interlayer film 17 are formed on the Ru layer 19. An upper electrode 3 is embedded in the opening of the third interlayer film 17 and the upper electrode 3 is in contact with the resistance change layer 20. Ru is used for the upper electrode in the present example.

According to Example 5, the upper electrode 3 is formed to have a size smaller than that of the lower electrode layer including the TaN layer 18 and the Ru layer 19, and thus an area of the MIM structure is limited by a contacting area of the upper electrode 3 with the resistance change layer 20.

In an Example 5, a NMOS is used as the control transistor and a laminated structure as the ReRAM module is including: upper electrode (T.E.:Ru)/TaSiO film (8 nm in thickness)/TiO₂ film (2 nm in thickness)/lower electrode (B.E.:Ru/TaN laminated film). A ratio of silicon in the TaSiO film is Si/Ta=0.27.

An effect of silicon being mixed in a Ta₂O₅ film will be described.

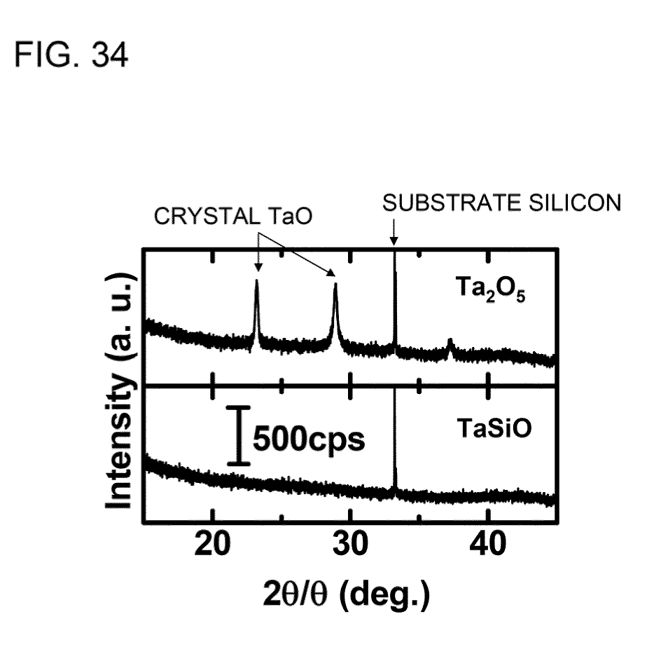

FIG. 34 shows an XRD (X-Ray Diffraction) spectrum of Ta₂O₅ film and TaSiO film after annealing at 750° C. for 30 minutes in nitrogen atmosphere. As shown in FIG. 34, peaks of crystalline TaO are observed in the XRD spectrum other than a peak of silicon in the substrate. Thus, it has been found that TaO is crystallized by the annealing at 750° C. for 30 minutes.

On the other hand, no peak can be seen in the spectrum of the TaSiO film other than the peak of silicon in the substrate. This means that thermal resistance of the Ta₂O₅ film is improved by addition of silicon to Ta₂O₅.

FIG. 35 shows a characteristic of current (I)-voltage applied on upper electrode (V_{T.E.}) at Forming time, Reset time and Set time. As shown in FIG. 35, it can be seen that a filament formation (Forming) and a decreasing of resistance (Set) occur by applying a positive voltage on the upper electrode and an increase of resistance (Reset) occurs by applying a negative voltage on the upper electrode also in the case where Si is added in the Ta₂O₅ layer.

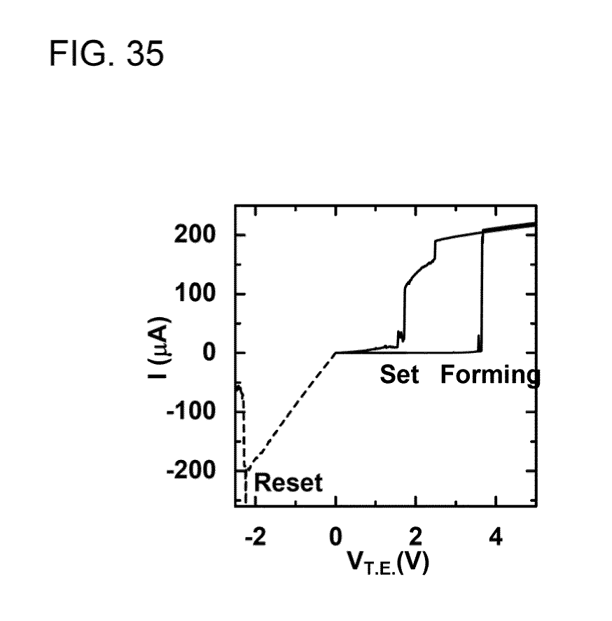

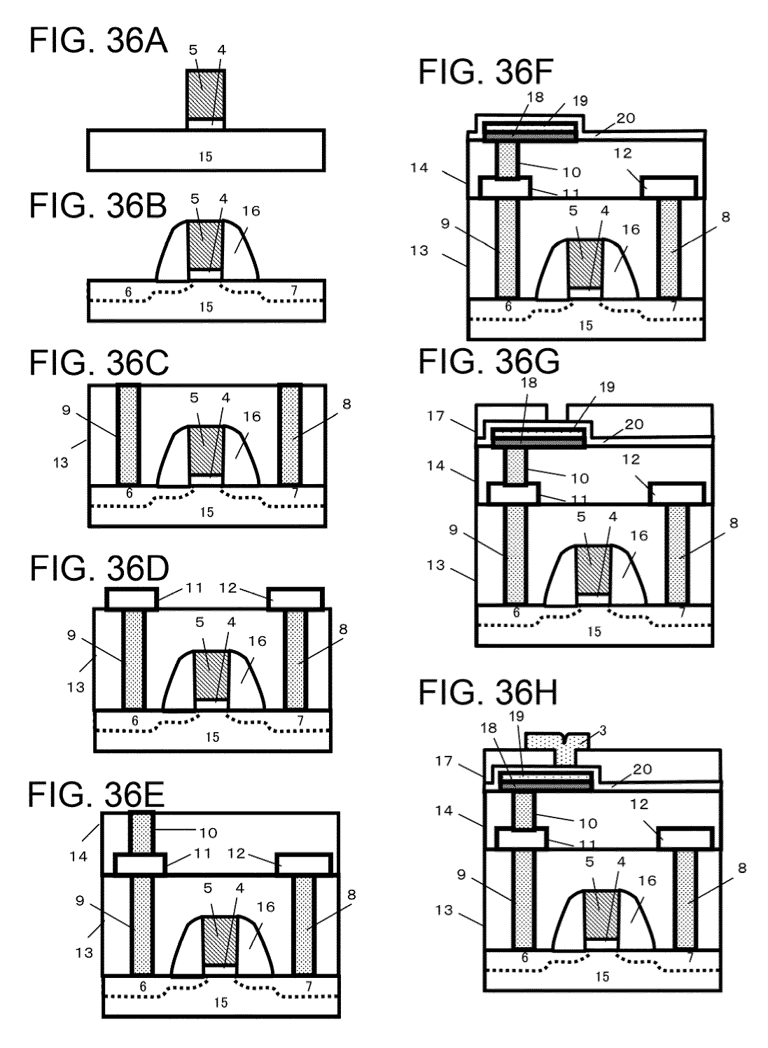

FIGS. 36A to 36H are sectional process diagrams illustrating the procedure of a fabrication method of Example 5 of the present invention. A fabrication method of Example 5 of the present invention will be described with reference to FIG. 36.

At first, as shown in FIG. 36A, a gate oxide film 4 and a phosphorous-doped polysilicone 5 are deposited on a semiconductor substrate 15, and then they are exposed and dry-etched for patterning to form a gate electrode 5.

Next, as shown in FIG. 36B, gate side walls 16 are formed by an insulation film deposition process and a dry etch-back process. Source/drain regions 6 and 7 are formed by doping phosphor with a dose of 2E+15 cm⁻² using the gate electrode 5 and the gate side walls 16 as a mask.

Next, as shown in FIG. 36C, a first interlayer insulation film 13 is deposited on an entire surface of the semiconductor substrate 15 and the surface of the film is flattened by CMP. An oxide film is used for the first interlayer insulation film 13 in the present example.

Next, the first interlayer insulation film 13 is exposed and dry-etched to perforate the film to make vias, and TiN (titanium nitride) and W (tungsten) are deposited.

The surface is flattened by CMP and the deposited TiN and W portion other than via portions is eliminated to form vias 8 and 9.

Next, as shown in FIG. 36D, TiN and Al (aluminum) are deposited in this order to form a metal interconnect layer and then the layer is exposed and dry-etched for patterning to form a first and a second interconnect layers 11 and 12.

Next, as shown in FIG. 36E, a second interlayer insulation film 14 is deposited on an entire surface of the semiconductor substrate 15 and a surface of the second interlayer insulation film is flattened by CMP. An oxide film is used for the second interlayer insulation film 14 in the present example.

Next, the first interlayer insulation film 14 is exposed and dry-etched to perforate the film to make a via, and TiN (titanium nitride) and W (tungsten) are deposited. The surface is flattened by CMP and the deposited TiN and W portion other than via portion is removed to form via 10.

Next, as shown in FIG. 36F, a TaN layer 18 of 20 nm thickness and a Ru layer 19 of 40 nm thickness are deposited and the layers are exposed and dry-etched to form a lower electrode (laminated structure including the TaN layer 18 and the Ru layer 19).

Next, a TiO₂ film of 2 nm thickness and a TaSiO (Si/Ta=0.27) of 8 nm thickness are deposited sequentially to form a resistance change layer 20.

A DC sputtering equipment is used for the deposition of TiO₂ film. Ti is used as a sputtering target, and a flow rate of O₂ and Ar is 1:5. Pressure in a chamber is set to 10 mTorr, the film deposition temperature is set to 300 degrees and supplied power is 4.2 kW.

An RF sputtering equipment is used for the deposition of TaSiO film. Ta₂O₅ is used as a sputtering target, and 10 sccm of O₂ gas and 20 sccm of Ar gas are flown. The film deposition temperature is set to 350° C. and, power is 3 kW.

Next, as shown in FIG. 36G, a third interlayer insulation film 17 is deposited on an entire surface of the semiconductor substrate 15 and the surface of the third interlayer insulation film is flattened by CMP. An oxide film is used for the third interlayer insulation film 17 in the present example.

Next, the lower electrode 1 is exposed and dry-etched to form an opening.

Next, as shown in FIG. 36H, a Ru film of 40 nm thickness is deposited and the Ru film is exposed and dry-etched to form an upper electrode 3.

An area of the MIM structure is limited by a contacting area of the upper electrode 3 with the resistance change layer 20.

In case Ta₂O₅ of the ReRAM module is replaced with TaSiO, tolerance against process heat stress can be improved and hence high reliability can be attained even if many wiring steps are added after the formation of the ReRAM module.

Each disclosure of the abovementioned Non-Patent Documents is incorporated by reference into the present document. Modifications and adjustments of embodiments and examples are possible within bounds of the entire disclosure (including the range of the claims) of the present invention, and also based on fundamental technological concepts thereof. Furthermore, a wide variety of combinations and selections of various disclosed elements is possible within the scope of the claims of the present invention. That is, the present invention clearly includes every type of transformation and modification that a person skilled in the art can realize according to technological concepts and the entire disclosure including the scope of the claims.

What is claimed is:

1. A resistance change type memory device, comprising:
a first electrode;
a second electrode; and
an insulation film sandwiched between the first electrode and the second electrode, the first electrode, the insulation film and the second electrode constituting an MIM (Metal/Insulator/Metal) structure, wherein the insulation film comprises
a Ta₂O₅ film and a TiO₂ film forming a laminated structure, the TiO₂ film having a thickness of less than 30 nm.

2. The resistance change type memory device according to claim 1, wherein the Ta₂O₅ film includes a stoichiometric amorphous film.

3. The resistance change type memory device according to claim 1, wherein the TiO₂ film includes a Rutile structure.

4. The resistance change type memory device according to claim 1, wherein the first electrode is in contact with the TiO₂ film.

5. The resistance change type memory device according to claim 1, wherein the first electrode comprises Ru or Pt.

6. The resistance change type memory device according to claim 1, wherein the first electrode comprises
one of a laminated structure including a Ru layer and a TaN layer, and a laminated structure including a Pt layer and a TaN layer,
the TiO₂ film being in contact with the Ru layer or the Pt layer.

7. The resistance change type memory device according to claim 1, comprising
a mutual diffusion layer of Ti and Ta between the Ta₂O₅ film and the TiO₂ film.

8. The resistance change type memory device according to claim 1, wherein silicon is mixed in the Ta₂O₅ film.

9. A method for operating a resistance change type memory device, comprising:
using a laminated structure including a Ta₂O₅ film and a TiO₂ film with a thickness of less than 30 nm as an insulation film of an MIM (Metal/Insulator/Metal) structure in which the insulation film is sandwiched between first electrode and a second electrode; and
causing a function of a resistance change memory to become effective.

10. The method according to claim 9, comprising:
applying a voltage across the first electrode and the second electrode so as to make a resistance between the first electrode and the second electrode smaller than a resistance of a single layer of the Ta₂O₅.

11. The method according to claim 9, arranging a mutual diffusion layer of Ti and Ta between the Ta₂O₅ film and the TiO₂ film.

12. A semiconductor device comprising:
a first electrode formed on an interlayer insulation film arranged on the semiconductor substrate and connected through a via to a diffusion layer of a transistor formed on a surface of the semiconductor substrate;
a laminated insulation film arranged on the first electrode and including a TiO₂ film with a thickness of less than 30 nm and a Ta₂O₅ film; and
a second electrode arranged on the laminated film,
the semiconductor device including an MIM (Metal/Insulator/Metal) structure in which the laminated insulation film is sandwiched between the first electrode and the second electrode.

13. The semiconductor device according to claim 12, wherein the Ta₂O₅ film includes a stoichiometric amorphous film.

14. The semiconductor device according to claim 12, wherein the TiO₂ film comprises a Rutile structure.

15. The semiconductor device according to claim 12, wherein the first electrode comprises Ru or Pt.

16. The semiconductor device according to claim 12, wherein the first electrode comprises
one of a laminated structure including a Ru layer and a TaN layer, and a laminated structure including a Pt layer and a TaN layer,
the TiO₂ film being in contact with the Ru layer or the Pt layer.

17. The semiconductor device according to claim 12, comprising
a mutual diffusion layer of Ti and Ta arranged between the Ta₂O₅ film and the TiO₂ film.

18. The semiconductor device according to claim 12, wherein silicon is mixed in the Ta₂O₅ film.

19. The semiconductor device according to claim 12, comprising:
the first electrode connected through a via to a first diffusion layer of the transistor on the semiconductor substrate;
a resistance change layer arranged on the first electrode, the resistance change layer comprising a laminated structure arranged on the first electrode and including the TiO₂ film with a thickness of less than 30 nm and the Ta₂O₅ film; and
the second electrode arranged on the resistance change layer, the first electrode, the resistance change layer, and the second electrode being arranged on a first interlayer insulation film covering the transistor formed on the semiconductor substrate, wherein
the second electrode is connected, through a via, to a first interconnect layer that is arranged on a second interlayer insulation film which is arranged on the first interlayer insulation film and which covers an MIM (Metal/Insulator/Metal) structure including the first electrode, the resistance change layer and the second electrode, and
a second diffusion layer of the transistor on the surface of the semiconductor substrate is connected, through a via, to a second interconnect layer arranged on the second interlayer insulation film.

20. The semiconductor device according to claim 12, comprising:
the first electrode connected through a via to a first diffusion layer of the transistor on the semiconductor substrate;
a resistance change layer of a laminated structure arranged on the first electrode and comprising the TiO₂ film having a specified thickness of less than 30 nm and the Ta₂O₅ film arranged on the TiO₂ film; and
the second electrode arranged on the resistance change layer,
the first electrode, the resistance change layer, and the second electrode being arranged on an interlayer insulation film arranged over the semiconductor substrate, wherein
an opening is provided in another interlayer insulation film arranged on the interlayer insulation film, the opening that reaches the resistance change layer,
the second electrode is formed in the opening of the another interlayer insulation film, and
a second diffusion layer of the transistor on the surface of the semiconductor substrate is connected to an interconnect layer of a preset layer through a via.

21. The semiconductor device according to claim 12, wherein a voltage applied on a gate electrode is adjusted to perform current limiting and to set a resistance value of the resistance change layer to a desired value, when a positive voltage is applied on the first interconnect layer and the gate electrode of the transistor so as to reduce a resistance of the resistance change layer smaller than a resistance of a single layer of Ta₂O₅, and when a positive voltage is applied on the first interconnect layer and the gate electrode of the transistor at a time of switching from a high resistance state to a low resistance state of the resistance change layer.

22. A semiconductor device comprising a resistance change type memory device according to claim 1, wherein the first electrode of the resistance change type memory device is connected, through a via to a diffusion layer of a transistor on a surface of a semiconductor substrate.

23. A semiconductor device comprising a resistance change type memory device according to claim 1, wherein the first electrode of the resistance change type memory is arranged on an interconnect layer.

24. The semiconductor device according to claim 12, wherein a positive voltage is applied on the second electrode when reading a resistance value of the resistance change layer.

25. The semiconductor device according to claim 19, wherein the resistance change layer is causes to change into a high resistance state when a negative voltage is applied on the second electrode or when a positive voltage is applied on the second interconnect layer and the gate electrode of the transistor.

26. The semiconductor device according to claim 20, wherein the resistance change layer is caused to change into a high resistance state when a negative voltage is applied on the second electrode or when a positive voltage is applied on the interconnect layer of the specified layer and the gate electrode of the transistor.

27. A method for fabricating a semiconductor device, the method comprising:
depositing, on an interlayer insulation film on a semiconductor substrate, a first conductive film connected through a via to a diffusion layer of a transistor arranged on a semiconductor substrate, a laminated film including a TiO₂ film with a thickness of less than 30 nm and a Ta₂O₅ film, and a second conductive film; and
forming an MIM (Metal/Insulator/Metal) structure, using an exposure process and an etching process, in which the laminated film is sandwiched between a first electrode including the first conductive film and a second electrode including the second conductive film.

28. The method according to claim 27, comprising:
depositing, on the interlayer insulation film on the semiconductor substrate, the first conductive film connected through a via to the diffusion layer of the transistor arranged on the semiconductor substrate and patterning the first conductive film into the first electrode by exposure and etching process;
depositing the laminated film including a TiO₂ film with a thickness of less than 30 nm and a Ta₂O₅ film on a substrate including the first electrode;
depositing another interlayer insulation film covering the interlayer insulation film and the laminated film;
forming an opening in the another interlayer insulation film at a position corresponding to the first electrode, the opening reaching an surface of the laminated film including the TiO₂ film and the Ta₂O₅ film and then depositing the second conductive film; and
patterning the second conductive film into the second electrode by exposure and etching processes to form the MIM (Metal/Insulator/Metal) structure including the laminated film sandwiched between the first electrode and the second electrode.
